(19) United States
(12) Patent Application Publication
(10) Pub. No.: US 2015/0027516 A1
(43) Pub. Date: Jan. 29, 2015

(54) BACKSHEET AND PHOTOVOLTAIC MODULES COMPRISING IT

(71) Applicant: RENOLIT BELGIUM N.V., Oudenaarde (BE)

(72) Inventor: Francois Rummens, Bruxelles (BE)

(73) Assignee: RENOLIT BELGIUM N.V., Oudenaarde (BE)

(21) Appl. No.: 14/384,718

(22) PCT Filed: Mar. 5, 2013
(86) PCT No.: PCT/EP2013/000629

§ 371 Date: Sep. 12, 2014

(30) Foreign Application Priority Data
Mar. 12, 2012 (EP) 12001690.2
Apr. 28, 2012 (EP) 12003009.3
Sep. 10, 2012 (EP) PCTEP2012003788

(51) Int. Cl. H01L 31/048; B32B 27/08; B32B 27/32

(52) U.S. Cl. CPC H01L 31/0487; H01L 31/0481; B32B 27/32; B32B 27/08; B32B 2250/03; B32B 2250/246; B32B 2255/10; B32B 2262/101; B32B 2305/30; B32B 2307/7246; B32B 2323/04; B32B 2323/10; B32B 2323/046; B32B 2331/04; B32B 2377/00; B32B 2457/12
USPC 136/251; 136/256

(57) ABSTRACT

A coextruded backsheet on base of TPO layers, mainly FPP based layers and heat resistant and barrier layers, where the FPP layers dominate in the tensile strength of the backsheet by addition of fillers and the FPP layers have excellent long term heat stability by addition of specific heat stabilizers.

Thanks to its relative softness, the stresses on PV cells are reduced, compared to PET based backsheet. Advantageous combinations with VLDPE based encapsulants are described.

The present invention relates to filler(s), especially glass fibers, reinforced FPP based backsheets provided with an included oxygen and CO2 barrier layer, and where the FPP layer(s) have excellent long term heat stability by addition of specific heat stabilizers, excellent dimensional stability and softness, leading to improved PV module durability by at least the one of reduced mechanical stress on the PV cells and/or reduced mechanical stress on the interconnecting ribbon and/or reduced corrosion, even when electrical insulation PV module inner-layer(s) and encapsulant producing corrosive by products are used.

### BACKGROUND OF THE INVENTION

Usually, backsheets are multi-layers sheets and are produced in several steps. First, films are produced by extrusion and then such films are laminated with the help of adhesives to produce the backsheet. An example is the so called TPT backsheets, which are in fact a assembly of two Tedlar® films glued on both sides of a central PET film. The PET film brings the dielectric properties and the Tedlar films bring weathering protection. Such backsheets are quite stiff (E modulus of 3500 MPa) but have a low coefficient of linear thermal expansion (CLTE) of typically less than 40 10⁻⁶/K at 20° C.

Stiff backsheets increase the probability of failure of PV cells within PV modules, when PV modules (Glass/Encapsulant/interconnected crystalline PV cells/Encapsulant/Backsheet) are submitted to perpendicular load like wind and snow load. This is linked to the transfer of stress to the cells by the encapsulant films. Although a stiffer backsheet reduces the local maximum stress, the stress area is increased, meaning a higher probability of defects initiating a failure.

During thermal cycling, the PV cells are forced by the encapsulant films to follow the dilatation/contraction of glass and backsheet. The gap between the cells is increased when the temperature rises and reduced when the temperature drops. This leads to mechanical fatigue during thermal cycling of interconnecting ribbons between PV cells. The fatigue (and the amplitude of movement of gap between cells) is reduced when the backsheet gets softer and the Coefficient of Linear Thermal Expansion is reduced.

It is more cost effective to produce the back sheet by coextrusion (one step process) or coextrusion/co-lamination, where the main layer(s) are based on cost effective dielectric raw material like (Flexible) PolyPropylene. A one step process is obviously preferred for cost reason, meaning coextrusion of all layers in one step, possibly also the rear encapsulant (integrated adhesive backsheet). Flexible PolyPropylene is preferred, versus common PolyPropylene, to increase PV module durability.

A.o. to assure mechanical integrity of the backsheet during lamination (avoid perforation e.g. by soldering defects or loops in interconnecting metallic ribbon) but also to limit possible migration of cross-linkers and/or adhesion promoters and/or other additives from the encapsulation films into the backsheet and vice-versa, it is preferred to include in the backsheet a TPO incompatible, dielectric, heat resistant layer(s), which act(s) also as barrier layer, like Polyamide layer or layers or PET layer or layer(s).

Polyamide 6 is extremely cost effective for the purpose of heat resistance (avoiding risk of perforation, etc.) but is a poor dielectric (hygroscopic) and can only be used as part of a backsheet when protected against humidity by e.g. PP layers such as FPP layers.

Other requirements which are difficult to meet with Polyamide 6 are: good electrical insulation stability in humid conditions, UV stability, impact resistance, etc. Generally Polyamide is not suitable for long term exterior use and inclusion of polyamide within the backsheet is therefore preferred, to protect the Polyamide from the environment.

Integration of the rear encapsulant (also called back encapsulant) to the backsheet is possible by coextrusion and/or coextrusion/lamination and economical. When the rear encapsulant is pigmented, the heat resistant layer (PA, . . . ) is in such a case better protected against UV radiation.

Polyamide 6 can release water vapor during module production, leading to blisters, especially when reactive EVA encapsulants (comprising peroxide for crosslinking and free silanes) are used. Combination with more stable Polyolefin encapsulants (VLDPE based), instead of EVA is advantageous.

As part of a backsheet (e.g. to protect the polyamide layer), PP may be used, but is not preferred because of its brittleness and rigidity and high coefficient of thermal expansion, leading to internal stresses/fatigue in the PV module and risk of electrical shock (cracks in case of impact). Further PP can't be modified easily by fillers such as flame retardants, glass fibers, calcined kaolin, . . . without reducing further its impact properties.

Flexible Polypropylene, i.e. a blend of PP and rubber, is therefore preferred as being softer, impact resistant and leading therefore to less internal stresses inside the PV module and an higher reliability of electrical insulation, while FPP layers can easily be mixed with fillers.

The heat resistance (heat distorsion resistance) of Flexible Polypropylene is anyway relatively poor, leading to an higher rate of surface backsheet defects (at least esthetical) during module lamination.

This issue is partly addressed by selecting as polymeric component of layers of backsheet a Flexible PolyPropylene resin which brings a significant residual heat of fusion at lamination temperature of the FPP layers, preferably having an high viscosity (MFR<10 g/10 min at (230° C./2.16 Kg).

It is also required that the backsheet has good dimensional stability during module production (vacuum lamination typically at 150° C. and under pressure close to 1 atm) and induces limited stresses during cooling. Polypropylene and Flexible PolyPropylene films or layers have the tendency to flow and shrink at 150° C. and contract during cooling, leading to adhesion defects at the edges of the PV modules.

Lack of dimensional stability of multi-layer TPO (FPP) and PP based backsheet is an issue for the production process. Glass reinforcement of PP is useful, to reduce the coefficient of thermal expansion and improve thermal conductivity, but the material becomes very brittle and rigid, which leads also to internal stresses in the PV module. Glass reinforced PP backsheets, comprising an included layer on base of PA or PET are described in European (Divisional-) Patent Application No: 12006740.0 “Photovoltaic Modules”. FPP based backsheets and their combination with tie-layer to other layers are described in PCT/EP2009/000665 (“Photovoltaic modules and Production Process”), FPP based backsheets with improved processability and combination with integrated adhesives are described in patent application PCT/EP 2010/004335 (“Photovoltaic modules with Polypropylene based backsheet”) and in European patent application No: 10007553.0 (“Photovoltaic Modules using an adhesive integrated Heat Resistant multi-layer Backsheet”), The issue of lack of dimensional stability is described in European Patent Application No: 11003055.8 “Photovoltaic Modules comprising a mainly TPO based Adhesive integrated backsheet and a Front encapsulant film with excellent adhesion to the glass front sheet”.

Dai Nippon Printing patent application PCT/JP2006/323745 describes an encapsulant for a photovoltaic module comprising a resin for an encapsulant containing a silane-modified resin obtained by polymerizing an ethylenically unsaturated silane compound and polyethylene for polymerization, wherein the polyethylene for polymerization is a metallocene based linear low density polyethylene (LLDPE) having a density in the range of 0.895 g/cm³ to 0.910 g/cm³. Such products are relatively cost effective but stiff and lack of clarity. Such encapsulant will transfer severe stresses to the PV cells when the PV module (Glass/encapsulant/cells/encapsulant/backsheet) is put under load (snow load).

Dow patent application WO2008036708 (Electronic device module comprising polyolefin copolymer) describes encapsulants films which are based on polyolefin interpolymers of ethylene and a-olefin having a a-olefin content of between about 15, preferably at least about 20 and even more preferably at least about 25, wt % based on the weight of the interpolymer. These interpolymers typically have an a-olefin content of less than about 50, preferably less than about 45, more preferably less than about 40 and even more preferably less than about 35, wt % based on the weight of the interpolymer. Such interpolymers, referred to as VLDPE are, expensive, especially when the a a-olefin content is high. Such encapsulant have, especially when not crosslinked (<30% gel content), an Emodulus of more than 30 MPa and will still transfer more stresses to the PV cells than EVA encapsulants (Emodulus of typically 15 MPa), when the PV module (Glass/encapsulant/cells/encapsulant/backsheet) is put under load (snow load).

<<WO 2010/053936 (CO-EXTRUDED, MULTILAYERED POLYOLEFIN-BASED BACKSHEET FOR ELECTRONIC DEVICE MODULES)>> describes Multilayered Polyolefin Based Backsheet which have following layers:
A) a primer layer
B) an adhesive layer
C) a PO based layer having a melting peak greater than 145° C., i.e. a PolyPropylene.

The application addresses mainly the issue of inter-layer adhesion of multi-layer plastic films as such, but not in the application of PV modules. Delamination is mainly observed after PV module production, especially after aging and often as a result of interactions with encapsulants. The suitability of PolyPropylene for the application is also not discussed.

A layer of the primer layer can be replaced by PET or Polyamide, and may reinforce the backsheet. The PET or Polyamide is in such a case not protected anymore. Inclusion within the backsheet is preferred as disclosed in European (Divisional-) Patent Application No: 12006740.0 “Photovoltaic Modules”.

It is anyway currently required (conservative precaution) that backsheets have a Relative Thermal Index or RTI (see UL 746 B; IEC 61730-1) or RTE of at least 20° C. above the maximum operating temperature of the PV modules, which is commonly 85° C. or even 90° C. (Desert conditions) or even 95° C. (Building integrated modules). This means that backsheets need to keep at least 50% of their initial tensile strength after typically 20.000 hours of thermal aging in an oven at 105° C. (85+20° C.=105° C.), preferably 110° C. (90+20° C.=110° C.) or even more preferably 115° C. (95+20° C.==115° C.). The RTI or RTE of the backsheet should be at least 105° C., preferably 110° C., more preferably 115° C.

When looking to data's from the literature (e.g. Plastics Additives Handbook, 5^{th} edition, p. 81), it seems very difficult to achieve a RTI of 105° C. or more with PA and in particular PA 6 based backsheet.

Further, it has been observed that multi-layer backsheets, on base of polyolefins layers, tie-layers and polyamide, delaminate during aging, when the backsheet is combined with encapsulant(s) which are crosslinked by free radicals (peroxide) and when the polyamide is heat stabilized with classical Cu/I system. Alternatively, severe discoloration is observed when the Polyamide is stabilized with classical phenolic anti-oxydant instead of Cu/I systemI.

PP and FPP based backheet, not provided with a barrier layer between the encapsulant film and the PP layer(s), suffer also from the degradation of their anti-oxidant and mechanical properties by free radicals (from peroxide crosslinking, . . . ) attack.

Only expensive and less hygroscopic types of polyamides, e.g. polyamide 11 or polyamide 12 have found application in backsheets. Backsheets on base of Polyamide 12 in blend with polypropylene are supplied by Isovoltaic. After aging anyway (humidity, heat, UV, thermal cycling, exposure to peroxide attack from encapsulants), the material becomes brittle and cracks.

It may also be required that the backsheet has a high rigidity in order to limit the deflection of the PV module under load (e.g. snow). FPP based backsheet may be not rigid enough. This is anyway a prejudice. A frame (aluminium, . . . ) is the best way to greatly improve PV module rigidity.

PV cells are generally interconnected by so called interconnecting conducting ribbons (mainly tin plated copper ribbon). Such conducting ribbons will in many cases extend and cross under the backside of PV cells and need therefore to be electrically separated from the backside of the PV cells (electrodes) by an insulating inner layer (inner means inside the PV module, by opposition with backsheets, which are a PV module external layer).

A piece of classical backsheet like Tedlar/PET/Tedlar (TPT) or more generally a piece of a film comprising a PET film (like a multi-layer film of the type PE/PET/PE) between EVA encapsulants could be used for this purpose but this will lead to locally high concentration of detrimental (by-)products, in this case acetic acid.

PV modules may corrode locally, especially in the vicinity of the junction box, where inner separation layers are used to separate interconnecting ribbons. Local differences in Oxygen and corrosive products lead to local corrosion.

So, local severe corrosion may then be observed in hot and humid conditions, especially when inner-layer insulating films are used and backsheets, with high oxygen permeability and high permeability to such by-products (e.g. acetic acids), are used. The diffusion of the by-products from under those inner-layer on based of e.g. PET comprising films is much slower than the diffusion out of the module. Oxygen (O2) diffuses, on the other hand, quickly through the polyolefin based backsheet (poor oxygen barrier) and passivate metallic parts, except under those inner-layer.

In such a case of inner-layer insulating films being used, areas of locally higher concentration of corrosive by-products and reduced Oxygen access are created inside the PV modules versus region of lower concentration of corrosive by-products and higher oxygen concentration (passivation), creating concentration cells, well known to accelerate corrosion locally, for example:
i. The region between the cells backside and the PET comprising separation layer, e.g. TPT insulating layer, traps acetic acid by-products of EVA degradation and the corrosion attack, e.g. of conductive ribbon, is significantly increased in that area.
ii. The other regions let acetic acid escape, through the backsheet, from the PV module, while oxygen is admitted (passivation) and corrosion is kept limited.

It has to be realized that not only encapsulants are the source of corrosion by-products, but also degreasing treatment of the interconnecting ribbon. When locally residual treatment initiate local corrosion, it is desired to have a backsheet with reduced oxygen permeability in comparison with pure Polyolefin based backsheets.

As during production and aging of PV modules, detrimental (by-) products e.g. corrosive by-products, especially acids, like acetic acid from EVA encapsulants or like acrylic or maleic acids from tie-layers, etc. are often released by encapsulants, it is advantageous to use a backsheet which is permeable to such products, allowing them to escape easily from the PV modules reducing their detrimental effect.

Classical backsheets comprising a PET film are a relatively good barrier against migration of by-products such as acetic acid and limit egress of such by-products from the PV module.

Classical backsheets comprising a PET film have also, compared to polyolefin based backsheet, a relatively good oxygen barrier effect, which reduce the risk of corrosion.

Polyolefin based backsheet are cost effective and hydrolysis resistant but poor oxygen and CO2 barriers.

It is therefore advantageous that the polyolefin based backsheet is provided with an oxygen and preferably CO2 barrier layer, most preferably still permeable to degradation by-products.

Further, when Polyolefin based backsheets are used, with high oxygen permeability, and modules comprise inner-layers which are good oxygen barrier, a local depletion of oxygen may also result, meaning locally reduced passivation and enhanced corrosion.

Further, classical TPT backsheets and Polyolefin based backsheet are poor barrier against CO2. Such gas is at the origin of Snail Trail effect as described in “Microscopy study of snail trail phenomenon on photovoltaic modules” (Peng Peng; Anming Hu; Wenda Zheng; Peter Su; DOI: 10.10391c2ra22280a).

PV modules catching fire is an increasing concern which needs to be addressed. It is well known to attach at the rear side of the PV module, a fire barrier like a close fabric on base of glass fibers. Such attachment is done in a supplementary step with adhesives. A more cost effective way is desired.

As conclusion, there is still a need of a cost effective backsheet, i.e. preferably a coextruded backsheet, provided with a heat resistant layer or layers, acting also as oxygen and preferably CO2 and/or additives barrier, the backsheet having excellent long term heat and UV stability and hydrolysis resistance and delamination resistance after aging of PV modules, even when combined with peroxide containing encapsulants, and limited hygroscopicity and good processability during module lamination and flame retardancy and reduced CLTE and impact resistance, and preferably good degradation by-product permeability, and/or combination with a rear encapsulant (adhesive integrated), such encapsulant preferably not requiring crosslinking, while the combination backsheet/rear encapsulant doesn't lead to excessive stress on PV cells even when the integrated rear encapsulant is stiffer than usual rear encapsulants like EVA, and/or easy combination with fire barrier, preferably during module lamination and without supplementary adhesives.

### SUMMARY OF THE INVENTION

Within the scope of this invention, a photovoltaic module (also abbreviated PV module) comprises at least the following layers/components:
a transparent front layer, preferably glass
encapsulant film(s) (also called potant film or layer), possibly with reduced amount of polymers producing acidic degradation by-products
possibly an area sensitive to local corrosion with as examples:
   locally contaminated metallic ribbons
   adhesive layer(s), containing or releasing detrimental (by-)products, especially corrosive (by-)products, more specifically acidic (by-)products like e.g. acetic, acrylic acid or maleic acid, during module production and/or in use (after aging and hydrolysis of polymeric encapsulants), and a piece of electrically insulating film (separation layer) creating concentration inhomogeneïty of by-products and oxygen within the PV module, i.e. located between (interconnecting) conducting ribbon and PV material electrodes, trapped by the PV module inner-layer (inner-layer, by opposition to backsheet which is an external layer)
an active layer comprising a photovoltaic material sandwiched between a front and a back electrode layer
(interconnecting) conducting ribbon or other means to interconnect PV cells
a backsheet.

It is one of the object of the present invention to limit the risk of local corrosion. This is best achieved with the backsheet of this invention, preferably on base of polyamide and Flexible PP layers, which allow high egress of detrimental by-products, like acetic acid or other acids, this compared to PET based backsheets, and has improved oxygen and CO2 barrier properties, this compared to Polyolefin based backsheets.

Further the backsheet has good processing properties (heat distorsion, dimensional stability) and limited CLTE, thanks to the high filler content and leads to limited stress on PV cells and interconnecting ribbons thanks to its softness.

Further, the backsheet composition (FPP layers) can be flame retarded without becoming brittle.

Further, the backsheet has long term heat, UV and hydrolysis stability and impact resistance to safeguard long term electrical insulation properties.

Further the backsheet is cost effective, being preferably produced in a one step process (coextrusion).

Therefore the backsheet of the invention comprises mainly, preferably coextruded:
TPO layers, especially FPP based layer or layers,
preferably an oxygen and CO2 barrier layer, like a Polyamide based layer,
   where the FPP layer(s) are heat stabilized to achieve a RTI of 105° C. or more and comprise fillers and reinforcing fillers:
to provide dominance in mechanical properties versus the oxygen barrier layer (polyamide, . . . if included)
to improve solar reflectance, flame retardancy, thermal conductivity, dimensional stability,
to reduce CLTE,
to increase heat distorsion (better resistance against deformation/indentation during lamination, e.g. by the interconnecting ribbon).

Useful FPP compositions are described in patent applications PCT/EP 2010/004335 (“Photovoltaic modules with Polypropylene based backsheet”), EP No: 10007553.0 (“Photovoltaic Modules using an adhesive integrated Heat Resistant multi-layer Backsheet”) and PCT/EP2009/000665 (“Photovoltaic modules and Production Process”).

Useful oxygen and/or CO2 barrier layers are based a.o. on PA 6, PA MXD6, PA Selar (6I/6T), . . . or blends thereof and are described in “Ultramid® Film properties and applications (Dr. Grützner, 05-2008, BASF SE)” and in “Les plastiques à effet barrière dans l'emballage; F. Monfort-Windels; Revision November 2007”.

The multi-layer nature of the backsheet, comprising preferably layers of different melting temperature and reactivity eases the automation of production of PV modules (quick welding of junction boxes and accessories instead of slow gluing of the same) and also quick attaching of a fire barrier (during module lamination).

Polyamide Based Layer or Layers:
improve the heat resistance of the backsheet, i.e. helps achieving mechanical integrity (e.g. reduced risk of perforation of the backsheet by soldering defects or loops between metallic ribbons) during lamination of the backsheet
and, when relevant, protect the TPO (e.g. FPP) layer or layers and its stabilizers from the negative effects of peroxides or generated free radicals, migrated from encapsulating films, being understood that at least a barrier layer is located close to the encapsulant film, i.e. in contact with the primer layer of the backsheet at the side of the encapsulant.
and reduce the oxygen (risk of local corrosion) and the CO2 (risk of snail trail effect) permeability of the backsheet (being understood that only polyolefin based backsheet are very poor oxygen and CO2 barriers).
and avoid or reduce cross-migration of additives from encapsulants and backsheet.

TPO Layers:
Thanks to the use of fillers reinforced soft TPO (e.g. FPP) based layers, the backsheet has a.o. a good heat distorsion resistance and a relative low E modulus (compared to TPT backsheets with a Emodulus of 3500 MPa) of less than 2500 MPa, preferably of less than 2000 MPa, more preferably of less than 1500 MPa and most preferably of less than 1000 MPa and a low CLTE (coefficient of linear thermal expansion) of preferably less than 100 10⁻⁶/K at 20° C. Therefore, the backsheet of the invention allows to produce PV modules of good quality (low rate of defects) without excessive stresses on the PV cells and fatigue of the interconnecting ribbons.
TPO layers of lower melting temperature can easily be provided as external layers, e.g. by coextrusion, of the backsheet to ease adhesion with other layers (encapsulants, aluminium frame at cell side, and fire barrier and/or Junction Box, etc, at opposite side). Such layers can be functionalized to provide adhesion by chemical reactions.

By adapted formulation (anti-oxidants and/or fillers content and/or polymeric modification) and thickness ratio of the layers, the backsheet achieves a long term thermal stability temperature (Relative Thermal Index or RTI; UL 746 B; Relative Thermal Endurance or RTE according IEC 61215 (2005-04) part 10.13 or IEC 61646 (2008-05) part 10.13) of 105° C. or more and excellent Partial Discharge behavior (low dielectric constant).

Integration to the soft backsheet of a relatively stiff LLDPE or VLDPE based rear encapsulant is possible, with limited impact on the PV cells. Relatively stiff means a sufficient DSC peak melting temperature of higher than 70° C. In such a case, the rear encapsulant doesn't need peroxide cross-linking, which is advantageous. Further:
The more rigid back encapsulant reduces the fatigue of interconnecting ribbons in harsh climates with severe thermal cycli (e.g. in desert climates) because it restricts the amplitude of movements within the cell gaps (lower amplitude of opening/closing movements and less fatigue of ribbon as consequence).
The softer and more relaxing backsheet compensate the increased stress transmitted by the stiffer rear encapsulant to the PV cells under load (like snow load)

Innovative encapsulants are also proposed, comprising a apolar co-PE layer acting as ion migration barrier and soft polar co-PE layer(s), like EVA layers, allowing achieving high transparency, softness, low cost and limiting the phenomena of PID (Potential Induced Degradation) of Crystaline Silicone PV cells.

A cost effective combination is proposed of innovative backsheet comprising FPP layer(s) and encapsulants on base of EVA and VLDPE layers limiting the phenomena of PID and risk of local corrosion.

Electrically insulating inner layer are described, reducing the risk of local corrosion.

It is one of the object of the present invention to limit the concentration of detrimental (by-) products, especially corrosive products released from encapsulants inside PV modules, especially to limit locally high concentrations of such detrimental (by-) products.

The invention addresses especially the problem of generation and trapping of acid(s) within crystalline PV modules, where such modules comprise encapsulant material at least partly on base of EVA or at least partly on base of other acid generating material like co-Polyethylene (grafted) with acrylates, acrylic acids, maleic anhydrides.

For this purpose, the invention provides insulating films with high permeability to this detrimental (by-) products, i.e. allowing this detrimental (by-) products to escape from the PV modules or at least to limit local high concentrations. The invention is particularly useful with backsheets with high permeability to detrimental (by-) products and to oxygen as such backsheets will lead to high concentration differences within the PV module.

The main solution to the issue of high concentration differences in Oxygen inside the PV module, is anyway a backsheet with good Oxygen barrier properties.

To possibly solve the problem of local concentration differences, one provides:

A) An electrical insulating piece of film to electrically separate (insulate) conductive ribbons from other conductive parts of the PV modules, like PV cells, such a piece of film having a high permeability to detrimental (by-) products (e.g. by micro-perforation or by being on base of permeable materials) preventing such (by-) products from being locally trapped,
B) Preferably encapsulants with reduced generation of detrimental by-products.

The issue of local corrosion is solved by the invention, at low cost, by at least the one of:
i. Providing a cost effective, i.e. preferably produced by coextrusion, TPO based backsheet equipped with an oxygen barrier layer, typically on base of Polyamide or EVOH or Polyester (PET, . . . ) or PVDC based, or blends thereof, possibly with fillers like platelets (plate shape) like talcum, clay, kaolin, possibly calcined, mica, etc., where the thickness of the oxygen barrier layer is typically ranging from 1 μm to 150 μm, preferably from 5 to 100 μm. The oxygen barrier layer is to be understood in reference to polyolefin (poor barrier) and is a polymeric based material, possibly with fillers, having an Oxygen Transmission Rate in a thickness of 25 μm of from typically 0.002 to 100 cc/m².day.atm. (measured at 50% R.H. 23° C.), as exposed in “Ultramid® Film properties and applications (Dr. Grützner, 05-2008, BASF SE)”
ii. If present, an electrically insulating film (separation layer) between (interconnecting) conducting ribbon and PV material electrodes, with good permeability to detrimental (by-) products and oxygen e.g. by micro-perforation and/or by a composition which is highly permeable to such (by-) products and oxygen

Polymeric material with good oxygen and CO2 barrier properties are known per se but a useful list is provided in “Ultramid® Film properties and applications (Dr. Grützner, 05-2008, BASF SE)” and in “Les plastiques a effet barrière dans l'emballage; F. Monfort-Windels; Révision November 2007”.

Polyolefins are bad barrier to Oxygen and CO2 but good water vapor barriers.

PA MXD6, PA 6I/6T, EVOH and PA 6 are preferred materials as such or in blend. PA 6 is cost effective but hygroscopic.

PA MXD6 or PA 6I/6T are better barriers and less hygroscopic.

The man skilled in the art will define the thickness of the barrier layer to achieve an Oxygen Transmission Rate (OTR) of the backsheet of less than 100 cc/m².day.atm at 23° C. 50% relative humidity, more preferably less than 50 cc/m².day.atm at 23° C. 50% relative humidity, even more preferably of less than 25 cc/m².day.atm at 23° C. 50% relative humidity.

PA, PA/EVOH, EVOH and blends thereof are excellent CO2 barrier. Useful CO2 barrier are best described in “Les plastiques à effet barrière dans l'emballage; F. Monfort-Windels; Révision November 2007”. CO2 barrier is advantageous to delay/reduce the snail trail effect of crystalline silicon PV modules (see Microscopy study of snail trail phenomenon on photovoltaic modules; (Peng Peng; Anming Hu; Wenda Zheng; Peter Su; DOI: 10.1039/c2ra22280a)).

Fillers (plate shape) are useful to increase tortuosity and to improve barrier properties.

Useful polymeric materials which are permeable to acetic acid are PA 6, PP blends comprising rubbery material (Flexible PolyPropylene), co-PE (VLDPE, LLDPE, EVA, . . . ), Polyamide 12 and 11, and blends thereof.

Useful polymeric materials which are permeable to oxygen are PP, PE and co-PE (VLDPE, LLDPE, EVA, . . . ) and in some extend Polyamide 12 and 11, and blends thereof. Such materials are a.o. useful to produce a separation inner-layer (electrical insulation inner-layer) with good permeability to oxygen and degradation by products. A useful film for such separation inner-layer application comprise following structure: tie-PE/PA12-PP blend/tie-PE.

PA 6 is a barrier to O2 and CO2 and permeable to acetic acid and is cost effective.

Polyolefins are relatively good water vapor barrier. Limiting the amount of rubber (low melting temperature material) and/or polar comonomers improves water barrier properties. Dielectric properties are improved by fillers (kaolin, mica, . . . ).

To avoid acetic acid generation, Polyethylene based encapsulant may also be used. Anyway, like for EVA, to obtain a high light transmission, Polyethylene with a high amount of comonomers (alpha olefin) needs to be selected, in particular metallocene VLDPE with a density of less than 0.915. In this case, the melting temperature of the Polyethylene is less than 110° C. (DSC melting peak temperature (ISO 11357-3). Softer VLDPE based encapsulants are preferred, meaning preferably a DSC melting peak temperature (ISO 11357-3) lower than 95° C., most preferably lower than 85° C., and even more preferably lower than 75° C. In such a case, it is safer to cross-link such encapsulation film thanks e.g. to addition in the formulation of free radicals initiators (peroxides, photoinitiators). VLDPE based encapsulants with a DSC melting peak temperature (ISO 11357-3) of less than 65° C. are especially advantageous as they have similar Emodulus or are softer than EVA, meaning equivalent or lower stresses on PV cells under snow load or during wind storms. Free radicals (peroxide) crosslinking is then compulsory.

Peroxide crosslinking is the usual method, as for EVA encapsulation films. In case the backsheet is made of polyolefin based layers (TPO—see PCT/EP 2010/004335, PCT/EP2009/000665), the peroxides from the encapsulant may migrate into such backsheet and may lead to degradation of especially the (Flexible) PolyPropylene based layers.

It has been discovered that inclusion in the backsheet of a not Polyolefin compatible layer, like a Polyamide based layer, separating the (Flexible) PolyPropylene based layers from the peroxide containing encapsulation films, will advantageously limit peroxide migration from the encapsulation films into the (F)PP based layers. As a result, peroxide “cracking” of the (F)PP layers is advantageously reduced. Excessive “Cracking” (depolymerisation) will lead to failure of the backsheet, especially when the (F)PP layers contain a high amount of fillers (like glass fibers), which reduce their elongation at break.

As a result of the inclusion of a peroxide barrier layer like a Polyamide based layer, cost effective backsheets comprising (F)PP based layers may be used in combination with peroxide cross-linked encapsulation films (EVA or VLDPE or EVA/VLDPE coextruded based). As a result, a cost-effective packaging of PV cells is made available under the form of a TPO based backsheet comprising a O2 and preferably CO2 barrier layer like a polyamide based layer, and peroxide cross-linked highly transparent and soft encapsulation films on base of EVA and/or VLDPE.

When VLDPE or EVA/VLDPE coextruded based encapsulation films are used, PID effect and risk of local corrosion are further reduced.

Cross-linking of VLDPE is less easy than cross-linking of EVA. To compensate for a lower cross-linking density, a VLDPE of higher DSC melting peak temperature (Tm) than typically 65° C. may be selected. Such VLDPE based encapsulant will be stiffer than usual EVA based encapsulants.

Encapsulants on base of coextruded EVA based layer(s) and VLDPE based layer(s), where the VLDPE has a Tm higher than 65° C., are anyway softer than encapsulants on base of the same VLDPE alone. This is advantageous to reduce stress on PV cells. Further such encapsulant can be combined with the softer backsheet of this invention to further compensate for higher Emodulus of encapsulant.

It has been surprisingly discovered that a synergy effect takes place by the combination of polar and apolar co-PE based layers (versus apolar Ico-PE based layers only), as far as the reduction of PID is concerned. This may be linked to local modification of the electrical field after partial (i.e. blocked by the apolar barrier layer) migration of ions towards the PV cell. A limitation of recombinations may occur as a result (with an increase of the shunt resistance as effect).

The invention further provides very cost effective backsheets with a.o. excellent acetic acid permeability, heat aging properties (RTI/RTE), even in contact with peroxide cross-linked encapsulants and dimensional stability during module manufacturing and reduced dielectric constant and hygrocopicity.

Polyamide is generally a poor dielectric. When polyamide is combined with polyolefins (PolyPropylene, PolyEthylene), it is possible to produce backsheet with excellent Partial Discharge behavior (reduced dielectric constant). This behavior defines the thickness of the backsheet. Combined means coextruded or blended.

The present invention describes a very cost effective backsheet comprising preferably thermally stabilized (i.e including anti-oxidants) Polyamide based layer(s), possibly PA6 based layer(s), and thermally stabilized Flexible Polypropylene based layers, which can be combined in such a way that the resultant backsheet achieves a RTI or RTE of 105° C., even 110° C. and even 115° C.

The Polyamide, e.g. Polyamide 6 based layer(s), if used, is/are protected by the FPP based layers which are laid at the backside of the backsheet (opposite side to the PV cells) in such a way that the Polyamide 6 based layer is protected from humidity and UV radiation. The FPP layer(s) allows also for easy welding to junction boxes, mounting accessories and/or framing.

TPO based backsheets (see especially PCT/EP 2010/004335 (“Photovoltaic modules with Polypropylene based backsheet”)) comprising a thick, i.e. having a reinforcing effect, polyamide layer or layers, e.g. PA 6 based and a Flexible Polypropylene layer or layers, can't, as such, achieve a RTI or RTE of 105° C. or more. When the Polyamide layer is degraded, the mechanical properties of the backsheet are reduced by more than 50%, even if the FPP layers are still effective (mechanical integrity).

It has been discovered that to achieve a RTI or RTE of more than 105° C. or preferably of more than 110° C., the Flexible Polypropylene layer or layers need to be heat stabilized and reinforced by reinforcing fillers, to dominate in the mechanical properties of the backsheet (i.e. avoid the polyamide layer(s) to reinforce the backsheet).

Alternatively, a RTI or RTE of 105° C. or more of the backsheet can also be achieved, when the reinforcing effect of the polyamide layer(s) is reduced by formulation modification of such layer or by selecting a low thickness of such layer compared to the thickness of the FPP layers (avoiding the reinforcing effect of the Polyamide layer).

For this purpose, the use of a polyamide with improved oxygen barrier properties is preferred, like PA MXD6 or PA 6I/6T, as for such Polyamide, when a reduced thickness is applied to avoid the reinforcing effect of the barrier layer, still good O2 and CO2 barrier properties are obtained, especially in humid conditions (e.g. Relative humidity of 85%).

With PA MXD6 for instance, sufficient barrier effect is achieved for a thickness of 25 μm or even 10 μm.

Sufficient barrier effect is climatic dependent but for the sake of illustration is defined as an OTR of less than 100 cc/m².day.atm, preferably less than 50 cc/m².day.atm., most preferably less than 25 cc/m².day (23° C., RH 50%). The same barrier effect of a bioriented PET film of at least 50 μm, preferably of at least 100 μm is also desired (all temperature from −40° C. to +85° C., all Relative Humidity conditions from 0 to 85%) as this type of film has demonstrated adequate O2 barrier properties in the field.

Polyamide (especially PA 6, PAMXD6) have in general better CO2 barrier properties than PET, which is advantageous (snail trail effect reduction).

To extend the durability of PV modules at low cost, it is preferred to use a backsheet which is mainly based on Flexible PolyPropylene, i.e. a blend of Polypropylene (PP) and rubber (EPR, EPDM, VLDPE, . . . ), where the PP phase and the rubber phase are co-continuous (i.e. providing an InterPenetrated Network of PP and Rubber) or are nearly co-continuous (semi-interpenetrated). Such type of blend allows by-products to migrate, probably along the rubber network, outside the PV module and leads to lower stresses on PV cells under load and to reduced fatigue of interconnecting ribbons during thermal cycli than PP (high rigidity—low relaxation of induced stresses).

“Thick” PP layers should not be used as part of backsheet of PV modules when the size of the PV module makes the contraction stresses significant. The man skilled in the art knows that a backsheet needs to have a thickness of typically 300 μm to allow modules to qualify for a system voltage of 1000 Volt, a common requirement. “Thick” needs to be understood in reference with this requirement.

The required quality of blend (a FPP blend by opposition to a PP blend) can be recognized and adapted by the man skilled in the art on base of cold foldability tests (according EN 495/5). The backsheet comprising FPP layers or at least the FPP layers, at least without fillers, should achieve a cold foldability temperature of at least −20° C., preferably −40° C. or lower.

Such backsheets are described in patent application PCT/EP 2010/004335 (“Photovoltaic modules with Polypropylene based backsheet”), in European patent application No: 10007553.0 (“Photovoltaic Modules using an adhesive integrated Heat Resistant multi-layer Backsheet”) and in PCT/EP2009/000665 (“Photovoltaic modules and Production Process”) which are incorporated herein by reference in their entirety.

To achieve high permeability to detrimental by-products like acetic acid, other polymeric materials and blends are also useful as base material for layers of backsheets and electrical insulating films, like Polyamide or Polyamide blends with Polyolefins, e.g. Flexible PolyPropylene. A good quality of blend of Polyamide and Polyolefin is achieved by the addition or use of functionalized polyolefin with e.g. maleic anhydride (reactivity with amides) or by adding a compatibilizing resin being a block copolymer of Polyamide and Polyolefins.

Polyamides, e.g. PA 6, 6-10, 11 or 12, are already useful as such as base material for layers of backsheets and electrical insulating films as they provide a good permeability to e.g. acetic acid. Nucleating agents may be added to the polymer to achieved desired crystallinity.

A very useful and cost effective backsheet is also proposed. Such backsheet comprises at least one Polyamide based layer, preferably on base of cheap polyamide 6, advantageously in blend with polyolefins (Polyethylene when improved resistance to peroxide cracking and impact is desired) and at least one (F)PP based layer where the (F)PP layer(s) is/are highly thermally stabilized.

The highly thermally stabilized (F)PP layer(s) is/are able to keep significantly more than 50% of their mechanical properties during 20.000 hours at 105° C., even at 110° C. and even at 115° C. (Such layer has a RTI or RTE of 105° C. or even of 110° C. and even of 115° C. according IEC 60216 (2001-07)).

When the contribution of the (F)PP layer(s) to the mechanical properties of the backsheet is dominant, it has been further discovered that after heat aging, 50% of the mechanical properties of the complete backsheet (including the PA layer or layers) can be kept, even when the mechanical properties of the polyamide layer(s) is/are nearly completely lost due to the thermal aging of such layer. In other words, it is preferred avoiding the polyamide layers being a mechanical reinforcement of the backsheet.

The contribution of the (F)PP layer(s) to the mechanical properties of the backsheet is made dominant by either stiffening the (F)PP layer(s) with fillers or by reducing the mechanical properties (elongation at break) of the polyamide based layer or layer(s) or by reducing the thickness of the polyamide based layer(s), or by combining the abovementioned actions. Other polymers than polyamide may be used for the barrier layer.

It has been discovered that after extreme degradation of the Polyamide based layer(s) during heat aging, there is no delamination between the (F)PP layer(s) and the PA layer(s), meaning that the integrity of the backsheet is safeguarded.

So, it has so been discovered that by adding fillers, especially glass fibers, in the Polyamide layer(s) and/or (F)PP layer(s), after thermal aging at elevated temperature (20.000 hours at Temperature of 105° C. or more), the tensile strength of the backsheet can still be of at least 50% of the initial value, without delamination of layers.

To increase the contribution of the (F)PP layers to the mechanical properties of the backsheet, the (F)PP layer(s) are preferably reinforced by fillers, e.g. by glass fibers, in such a way that the stiffened (F)PP layer(s) has/have the main contribution in the tensile strength of the backsheet.

Another way to increase the contribution of the (F)PP layers to the mechanical properties of the backsheet is to add fillers, especially glass fibers, in the polyamide layers. Such fillers will reduce the elongation at break of the polyamide layers (cutting effect). This is not the most desired way to proceed.

It will be further obvious for the man skilled in the art that reducing enough the total thickness of the polyamide layer or layers, will cause the (F)PP layers to become dominant in the mechanical properties of the backsheet. The total thickness of a backsheet is typically between 100 and 500 μm. As a first rule, the reinforcing effect of polyamide layer(s) will be lost when the total thickness of the polyamide layer or layers is much lower than typically 40% of the thickness of the total backsheet. A useful thickness for the polyamide layers should be between 1 and 40%, preferably 2 and 25%, most preferably between 5 and 20% of the total thickness of the backsheet.

When the total thickness of the Polyamide layers, especially PA6 layers is too high, the reinforcing effect on, and hygroscopicity of the backsheet (loss of dielectric properties in contact with humidity) will be too high.

Integration with a LLDPE or VLDPE based encapsulant is already an improvement as far as hygroscopicity is concerned (limitation of water take-up; less detrimental effect during module production e.g. lower risk of blisters). This integration is described in PCT/EP 2010/004335 (“Photovoltaic modules with Polypropylene based backsheet”).

When the thickness of the polyamide layer is too little, heat distorsion of the backsheet and separation effect (peroxide and additive migration barrier, . . . ) may be affected.

To keep the oxygen barrier effect and additive barrier effect, when a thin polyamide layer is considered, polyamide with better barrier properties will be selected, like PA MXD6 or PA 6I/6T. Intermediate barrier properties can be achieved when blending PA 6 and PA MXD6. Intermediate hygroscopicity will be achieved.

When the polyamide layer is reduced to less than 50 μm, FPP with a lower rubber content may be preferred and with an higher melting temperature.

When, as preferred, the barrier layer is an inner-layer of the backsheet, an aromatic polyamide (PA MXD6) or polymer can be used, because it is protected from light by light shielding co-PE layers and (F)PP layers. Impact resistance is provided by FPP layers.

Following structure is very useful:
A) Optional, at least partly opaque, heat and UV stabilized, Co-PE based layer, with high amount of TiO2 or light absorbing/scattering pigments or molecules, for adhesion with rear encapsulant (co-PE base)
B) at least partly opaque heat and UV stabilized functionalized Co-PE based layer for adhesion with barrier layer
C) light sensitive oxygen barrier layer (Polyester, polyamide, . . . based)
D) preferably at least partly opaque functionalized Co-PP based layer for adhesion with barrier layer
E) partly opaque heat stabilized FPP layer(s), preferably flame retarded

For white backsheet, the amount of TiO2 will be preferably of at least 5% weight, at least in layer A), B) and E), and preferably of at least 10%. Such high concentration in PP layers and other layers is easily possible when such layers are based on low crystallinity resins, like FPP blends.

A too high concentration (in % weight) of pigments in backsheet layers, especially layer B) (12b), will lead to pigment dispersion problems. It is therefore preferred to include in the backsheet the optional layer A) (12a), possibly as part of a rear encapsulant. Layer A) may preferably comprise from 5 to 20% weight TiO2 and have a thickness ranging from 25 to 450 μm or more. Such layer will efficiently protect the polyamide layer.

The shielding effect of pigments is dependant on concentration in layers and thickness of layers. It is more relevant to look to the concentration in grams of pigments per square meter of protective layer(s). For example, a layer of 100 g/m² comprising 10% weight of pigment has a area concentration of 10 g/m² of pigment. White pigments, especially TiO2 are preferred pigments, allowing also for solar reflectance. The TiO2 pigment is preferably a coated rutile type.

The protecting layers should provide together, per side of the backsheet, a area concentration of pigment of at least 1 g/m², preferably more than 5 g/m², more preferably more than 10 g/m² and even more preferably more than 15 g/m².

Alternatively, a thermally more stable Polyamide can be used, like Polyamide 11 or 12 to produce backsheets having a RTI (UL 746 B) of 105° C. or more. Addition of fillers may anyway still be required to limit initial mechanical properties (elongation at break) to reduce the reinforcing effect and to improve oxygen barrier effect (plate shape fillers). Blending with polyolefins is still useful for the dielectric properties and in this case, for cost reduction.

The backsheet comprises preferably one or more polyamide based layer(s) acting as heat resistant, anti-perforation layer(s) and migration barrier layer, during the module production (lamination at typically 150° C.) and thermally stabilized FPP based layers acting as insulating layers and having a RTI of 105° C. or more. Thermally stabilized (F)PP tie-layers having preferably a RTI of 105° C. or more are used as adhesive layers between the polyamide and the FPP layers.

Mainly FPP layer(s) on base of FPP having a DSC melting peak temperature (ISO 11357-3) above the module lamination temperature are preferred. More meaningfully, FPP materials having a substantial residual heat of fusion (enthalpy of melting) above module lamination temperature are preferred, i.e. the part of the peak of heat of fusion (enthalpy of melting) integrated from module lamination temperature upwards, should be more than 5 J/g, more preferably more than 20 J/g.

This is obvious to achieve e.g. by selecting a FPP blend, where the PP has a DSC melting peak temperature (ISO 11357-3) above module lamination temperature (typically around 150° C.), preferably 5° C. above, more preferably 10° C. above and where the rubber concentration (which has no enthalpy of melting at such temperature range) is limited to less than typically 70% (i.e. a more rigid blend).

It has been further discovered that a polyamide layer within the backsheet, facing the encapsulant films or layers (i.e. between the (F)PP layers and the encapsulant film), acts as barrier against migration of peroxides or other crosslinking agents from the encapsulant films. The (F)PP layers and their stabilizers are indeed sensitive (reactive) to such agents: it is important to reduce the attack of the (F)PP layers by peroxides (barrier effect of the polyamide layer). Without the barrier effect of the polyamide layer (or other suitable layer), such agents (peroxides and also silane adhesion promoters, crosslinkers) would be lost significantly by migration from the encapsulant films into the thick (F)PP layers and by unwanted reactions with the FPP layers and their stabilizers. In such a case, the cross-linking quality of the Encapsulant films and the durability of the (F)PP layers may be impaired. Further, discoloration (yellowing) may occur in heat damp test (aging at 85° C., 85% relative humidity).

A barrier effect for additive migration is required at lamination temperature (typically between 145 and 155° C.), which means that the barrier layer needs to be heat resistant and preferably incompatible with polyolefins. Interlayer adhesion is obtained on base of adhesive or preferably on base of tie-layers, by coextrusion. Useful incompatible and heat resistant polymers with polyolefins are e.g. polyamide and polyester resins (PET, PBT, . . . ). Heat resistant layers may be combined by coextrusion.

It has been discovered that the polyamide layer, facing the encapsulant layers, may require not to be heat stabilized in a classical way. Classical phenolic anti-oxidants lead to severe discoloration problems when cross-linkable encapsulant films are used (because of the curing agent, more precisely the free radicals from the initiator, like peroxide, attack of the phenolic group).

Copper/Iodine PolyAmide stabilizer systems lead to delamination of the tie-layers (functionalized polyolefin) when cross-linkable encapsulant films are used (peroxide attack of the Cu/I system and subsequent hydrolysis of chemical bonds between tie-layers and polyamide).

Specific anti-oxidants, if used, are required, like HALS (see Plastics Additives Handbook 5^{th} edition, p. 123 a 136) especially HALS 52 (Nylostab S-EED), and/or non phenolic primary anti-oxidants (amine based). Such above mentioned anti-oxidants are preferably used in combination with phosphite/phosphonite secondary anti-oxidants or other secondary anti-oxidants.

It is useful to add especially the secondary anti-oxidants with the help of a preferably functionalized polyolefin carrier based master batch, to avoid excessive reactivity during extrusion.

It has been discovered that using very specific phenolic anti-oxidant (ADK 80 supplied by Adeka, Irganox 245 supplied by BASF) within the polyamide layer which is exposed to migrated cross-linkers (peroxides, . . . ) from encapsulants, will lead to lower discoloration by heat and humidity of such polyamide layer than when stabilizing such polyamide layer with classical phenolic anti-oxydants (Irganox 1098, Irganox 1010, . . . ).

It has been discovered that the FPP layers, together with the tie-layers, provide excellent electrical insulation. A system voltage (IEC 60664-1:2007) of 600 VDC can already be achieved from a total thickness of the FPP layers and tie-layers of only 100 μm.

It is possible to design FPP based backsheets and layers allowing a system voltage of more than 1000 VDC and even of more 1500 VDC. This is theoretically possible with classical backsheets (Tedlar®/PET/Tedlar®, etc.) by increasing their thickness. Very rigid backsheets are anyway produced on such base, with excessive stresses on the PV cells as result. With FPP based backsheet, by increasing the content of rubber, the Emodulus can be reduced from >1500 MPa (PP) to <150 MPa (FPP with 70% rubber content), allowing the production of thicker backsheets, possibly glass fiber reinforced and/or with a high filler loading, with acceptable rigidity. A high filler loading is required e.g. to improve:
The reaction to fire of the backcheet: addition of flame retardants, preferably halogen free, with as example 30 a 40 parts of Magnesium Hydroxide (Mg(OH)2), per 100 parts of (F)PP resin.
The solar reflectance and UV opacitiy: addition of pigments, with as example 10 parts of TiO2, per 100 parts of (F)PP resin.
The dimensional stability and heat distorsion: addition of fibers, preferably glass fibers, with as example addition of 25 parts of glass fibers, per 100 parts of (F)PP resin.
The thermal conductivity: addition of glass fibers and/or mica are well known for such purpose, with as example addition of 25 parts of glass fibers, per 100 parts of (F)PP resin.
Electrical properties, with as example addition of calcined kaolin, . . . .

With such level of filler loading, common PP become too much brittle and stiff to be a reliable part of a backsheet.

Because the thermally stabilized FPP layer(s) and the (F)PP tie-layers achieve a RTI or RTE of 105° C. or more, the backsheet comprising such layers will be assigned a RTI or RTE of 105° C. or more. If the complete backsheet doesn't achieve such RTI or RTE of 105° C. or more, then to define the system voltage rating of the backsheet, only the layers achieving such RTI or RTE of 105° C. or more will be taken into account, e.g. 600 VDC from a total thickness of the FPP layers and tie-layers of only 100 μm.

While the polyamide layer(s) improve(s) mechanical integrity during the lamination of the PV modules and barrier effect (a.o. against peroxide migration towards (F)PP layers), the (F)PP layer(s) protect(s) the polyamide layer(s) against moisture ingress and UV aging and at least allows for excellent electrical insulation performances and partial discharge performances. The FPP layer(s) is/are like Polyamide 6, highly permeable to acetic acid. The FPP layer(s) is/are highly durable (thermal aging, UV aging, hydrolysis resistance) and resilient even at low temperature. The FPP layer(s) bring(s) excellent electrical insulation which is not reduced by development of impact crazes during aging (with as result a reduced partial discharge resistance), like it is the case for common Polypropylene.

Polyamide MXD6 is less permeable than Polyamide 6 to acetic acid, but can be used in a lower thickness while achieving sufficient oxygen barrier effect.

Polyamide 12 is also permeable to acetic acid.

It is advantageous to stiffen the Flexible PolyPropylene layer(s) by addition of fillers (talc, glass fibers, glass beads, etc) because of improvement the dimensional stability and resistance to flow under heat and load (lamination temperature and pressure) and reduction of perforation risk (during module manufacturing) of the backsheet. This means also surprisingly that the EVA encapsulant in contact with the front layer (typically glass, . . . ) will better adhere to the edges and corners of the front layer. This beneficial effect is observed already at low level of filler loading (typically from 5 to 15% weight of glass fibers).

Flexible PolyProPylene when blended with fillers is still advantageous compared to ordinary PolyPropylene (Emodulus of 1600 MPa or more and CLTE at 20° C. of 80⁻⁶/K), because the blend with filer is still more permeable to degradation by-products (acetic acid) and relatively flexible (typically a Emodulus of 1500 MPa or even of 1000 MPa or even less) and impact resistant, while the CLTE is at the level of PP (i.e. reduced from typically 200 10⁻⁶/K at 20° C. to typically 80⁻⁶/K at 20° C.) or less:
i. During aging, especially in hot and humid climates, because of higher permeability to acetic acid, the backsheet comprising a filler reinforced FPP layer, instead of an ordinary PP layer, will lead to better long term production of electricity (reduced corrosion of PV cells), when the cells are encapsulated into EVA encapsulants.
ii. During thermo-cycling (i.e. hot days and cold nights), because of lower Emodulus and CLTE, the backsheet comprising a filler reinforced FPP layer, instead of an ordinary filled PP layer, will lead to reduced fatigue of the interconnecting ribbon.
iii. Under snow load, because of the lower Emodulus, the backsheet comprising a filler reinforced FPP layer, instead of an ordinary filled PP layer, will lead to reduced probability of failure of the PV cells.

Glass fiber reinforced layers show some anisotropy depending on the process conditions. The Emodulus will be higher in the machine direction and lower in the cross machine direction. It is advantageous to align the lines of interconnecting ribbons with the cross machine direction of the backsheet. In such a case, under snow load, because the Emodulus is lower in the cross machine direction, the stress on the PV cells will be lower.

When the rear external layer of the backsheet, coming at the backside of the PV module (the side opposite to the side of the encapsulant), is based on a FPP blend, especially on a FPP reactor blend, or more generally a TPO, especially a functionalized TPO, it is easy to further weld/laminate components on the backside of the PV module (i.e. on the backsheet) like:
framing,
mounting hooks
junction box,
supplementary layers like glass or basalt fabrics (acting as fire barrier), provided such supplementary layers are equipped at the backsheet side with a similar polyolefin film or layer or are reactive with the functionalized TPO.

The back-sheet of this invention can indeed be coextruded at its rear side with PO tie-layers to serve as reactive adhesion layer with supplementary layers like glass or basalt fabric, during e.g. module lamination: the supplementary layers or fabrics, like amino-silane or epoxy-silane treated glass or basalt based fabrics will react during heat lamination and stick to the rear of the backsheet (by reaction with the PO tie-layer, being e.g. a co-PEgMAH). Adhesion with metal parts (aluminium frame or parts of frame) is also easy. On such metal parts, it is then further possible to attach new components, e.g. a continuous frame, when the PV module is cooled.

To improve the effect of the fire barrier during a fire, it is preferred that the fire barrier is attached to the backsheet with (partly) cross-linked adhesive. The functionalized PO tie-layers may therefore advantageously be partly crosslinked, e.g. by silane crosslinking. This means that silane cross-linkers (unsaturad silanes) are copolymerized or grafted to the backbone of such PO tie-layers.

The FPP layer(s) and polyamide layer(s) (or other heat resistant layer(s)) are preferably coextruded and attached to each other by polyolefin tie-layers. The resultant backsheet is in this case extremely cost effective, especially when the polyamide layer is further modified (blend) with polyolefins to improve its electrical performances (partial discharge behavior). Polypropylene is preferred to keep the heat resistance.

A very useful structure is (co-)PE tie-layer (encapsulant side)/PA based layer (or other heat resistant layer)/PP tie-layer/FPP glass fiber reinforced based layer.

To get easily good adhesion with fire barrier fabrics (glass or basalt base), following structure is useful: (co-)PE tie-layer (encapsulant side)/PA based layer (or other heat resistant layer)/PP tie-layer/FPP glass fiber reinforced based layer/EVAgMAH based tie-layer (reacting during lamination with e.g. amino or epoxy-silane treated fabrics).

To achieve excellent adhesion to encapsulant, the backsheet is preferably equipped at the encapsulant side with a (co-)PE based tie-layer or (co-)PE based tie-layer/(co-)PE based layer (encapsulant side) multi-layer, preferably opacified with pigments.

When the encapsulant(s) films is/are cured by e.g. peroxides (heat) and/or photoinitiators (UV), it is preferred that the backsheet contains a heat resistant layer, e.g. a polyamide based layer located between the encapsulants and the FPP layer(s) of the backsheet, in order to limit the amount of peroxides and free radicals which migrate to and attack the FPP (or PP) layers and their anti-oxidants. Indeed (F)PP and its anti-oxidants are sensitive to radicals (cracking) and side reactions may lead to discoloration (especially in Heat Damp Test, i.e. a climatic aging test at 85° C. 85% relative Humidity—1000 hours; according to IEC 60215 (2005-04) or IEC 61646 (2008-05)).

Further, it is desired to keep the peroxides and generated radicals and crosslinkers (like TAIC, . . . ) inside the encapsulant to increase crosslinking quality and avoid interference with the (F)PP layers and their anti-oxidants.

The invention further provides adapted encapsulants to limit generation of detrimental (by-) products and the phenomen of Potential Induced Degradation, which comprise a layer based on non polar co-PE.

The invention provides a very useful front encapsulant obtained by coextrusion of highly transparent polar co-polyethylene (e.g. EVA with a high amount of Vinyl Acetate) and non polar co-polyethylene (e.g; VLDPE). The EVA layers excel in transparency and compatibility with peroxides, photo-initiators, cross-linkers (TAC, TAIC) and silanes, while the VLDPE layer provides a barrier to migration of e.g. Sodium ions and reduces the production of acetic acid of the encapsulant. Excellent adhesion between layers is obtained after crosslinking (especially peroxide crosslinking). Thanks to the crosslinking, VLDPE of low melting temperature can be used (e.g. Exact 8230), which improves transparency.

The invention, further allows the combination of:
soft cost effective backsheets, with oxygen and possibly CO2 barrier layer, and
VLDPE or VLDPE/EVA based encapsulant, reducing the risks of local corrosion and PID effect.
   Where the low Emodulus of the backsheet compensates the possibly higher Emodulus of the encapsulant (compared to EVA). A stiffer than EVA rear VLDPE based encapsulant can be combined with the softer backsheet by and during e.g. coextrusion

### DETAILED DESCRIPTION OF THE INVENTION

### Definitions

Tensile E-modulus: Except otherwise stated, E-modulus are determined for a load of 1% tensile strain and at a tensile load speed of 1%/second, at 20° C., 50% Relative Humidity, after 3 days conditioning. If not otherwise stated, the film thickness is 350 μm.

PV cells: All types of PV cells may benefit from the invention, in particular crystalline PV cells.

p-type cells benefit of a front encapsulant with ion migration barrier.

Back contact PV cells benefit in particular from backsheets with integrated adhesive and electrically insulating films embedded within soft Polyethylene (like Organic Block Copolymers (OBC); trade name, Infuse™ from The Dow Chemical Company) based layers.

TPO means thermoplastic polyolefin and is any (blend of) thermoplastic polyolefins, including co-polyolefins and functionalized (co-)polyolefins, possibly with fillers and additives.

FPP is an example of TPO.

Soft TPO are TPO with a tensile Emodulus of less than 1500 MPa, preferably less than 1000 MPa, most preferably of less than 800 MPa.

Typical components of TPO are PP, EPR, EPDM, co-PE (functionalized co-PE like ionomers, EVAgMAH, PEcoGMA, or not functionalized), additives and fillers.

Within the scope of this invention, fillers are any material, which is not melted during the production of the backsheet, which increases the Emodulus of (i.e. reinforces) the polymer they are blended to. Preferred fillers are reinforcing fillers like fibers, especially glass fibers and plate shape (platelets) fillers like clays, nano-clays, kaolin, talcum, mica etc. Calcined fillers are useful for electrical properties. Other very useful fillers are flame retardants like Mg(OH)2, pigments, like TiO2, etc. Surface treatment of the fillers is of course useful (with silanes, titanates, etc.).

Flexible PolyPropylene (FPP) is a blend of Polypropylene (PP) and one or several elastomers or rubbers (EPR, EPDM, VLDPE, Elastomer PP . . . ), where the PP phase and the rubber phase are co-continuous (i.e. providing an Interpenetrated Network of PP and Rubber) or are nearly co-continuous.

An advantage of such blend is the ability to “accept” a high filler loading of easily more than 10%, of even more than 20% and of even more than 30%, while keeping impact properties, especially at low temperature.

Examples of suitable blends are:
i. Flexible polypropylene (FPP) mechanical or reactor blends of PP resins (homo or copolymer) with EPR rubber (ethylene propylene rubber), like “Catalloy®” reactor blends with as trade names Hifax CA 10 A, Hifax C212, Hifax CA 60, Hifax CA 02, Hifax CA 12 A, Hifax CA 138, Hifax CA7441A, etc. supplied by LyondellBasell. FPP blends with a Tg (TMA measurement 1 Hz) of less than −30° C. are preferred.
ii. Thermoplastic vulcanisates blends like Santoprene base blends. Such thermoplastic vulcanisates are based on blend of PP, with EPDM rubber and are considered within the scope of this invention as PP/EPR blends, which are partly crosslinked.
iii. Mechanical FPP blends of PP resins with elastomer PP resins (like supplied by Dow under the trade name Versify 2300.01 or 2400.01),
iv. Mechanical FPP blends of PP with LLDPE (linear low density polyethylene) or VLDPE (very low density polyethylene) plastomers (like Exact 0201 or Exact 8201 supplied by Dexplastomers), or copolymer of Ethylene with a polar comonomer like Vinyl Acetate or Alkyl Acrylates.
v. Blends obtained on base of 2 or more of the above mentioned blends.

The amount of rubber (EPR, EPDM, Elastomer PP, VLDPE, etc.) in the PP-rubber blend is of at least 30%, preferably of at least 40%, more preferably of at least 50% and even more preferably of at least 60% weight of the PP-rubber blend. This is especially the case when a high permeability to acidic by-products is desired.

When the thickness of the heat resistant layer (e.g. PA 6 based layer) inside the backsheet is reduced, the amount of rubber may also be reduced to a lower content of as low as 20%, to improve mechanical integrity of the backsheet at lamination temperature.

FPP reactor blends (produced by the Catalloy® process, i.e. the reactor granule technology) are especially preferred as component of the backsheet as the rubber phase dispersion is excellent, which is key for a high diffusion of the detrimental by products through the backsheet outside of the PV module, even when the ethylene percentage of the EPR is selected by the man skilled in the art to achieve better cold temperature performances (Tg<−30° C., preferably <−35° C.), i.e. meaning that the rubber phase has a reduced compatibility with PP and is more difficult to disperse by traditional mechanical blending). Softness at low temperature and impact resistance is required to keep insulation properties during module lifetime.

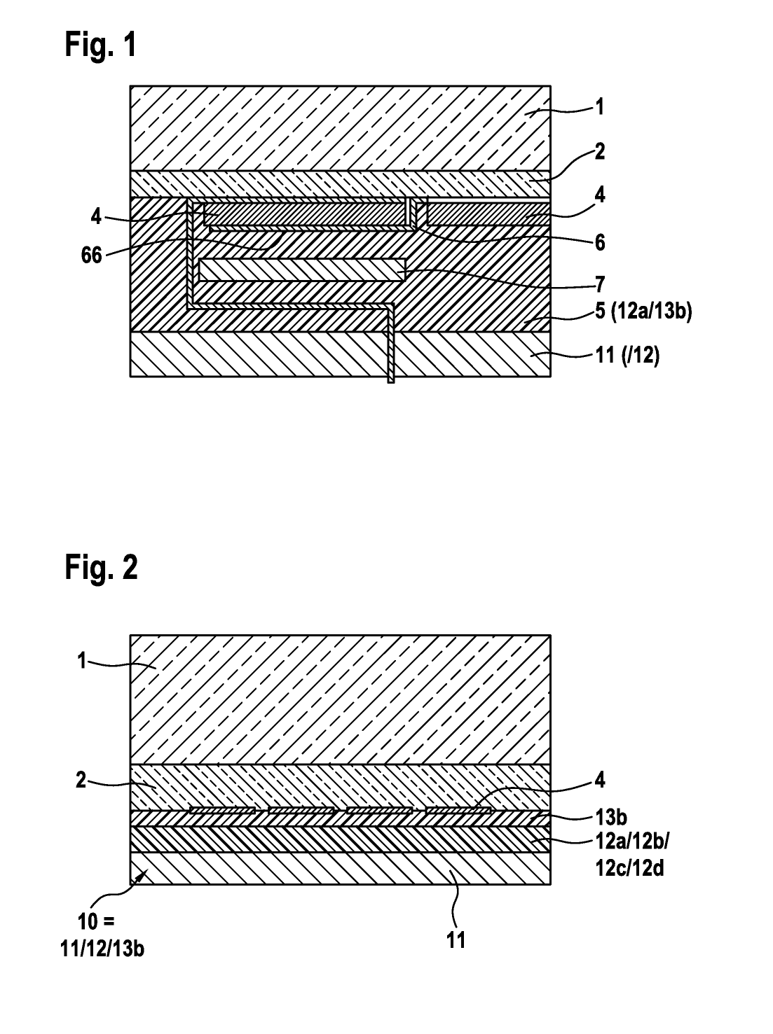

The amount of rubber can be estimated on base of comparative DSC analysis of the PP-rubber blend with the neat PP. While a Polypropylene will have a heat of fusion (DSC measurement; second heating at 10 K/minute)) of typically 100 to 110 J/g, the most useful FPP reactor blends will have a heat of fusion ranging from 15 to 60 J/g and of not more than 70 J/g, meaning a weight percentage of rubber phase typically from 40 to 80% and of at least 20% preferably 30%. The morphology (interpenetration) of such blend is well known in the art (see e.g. “Polypropylene: structure, blends and composites. J. Karger-Kocsis. Springer, 1995—p 17, FIG. 1.11).

Within the scope of this invention, the best ways to recognize a useful FPP blend based layer are by measurement of acetic acid permeability and by cold bending properties (cold foldability test according EN 495/5) of such film.

The acetic acid permeability measured at 60° C. should be of more than 20 g/m²*day for a film thickness of 0.5 mm (see test description later in the text).

The cold foldability of the film should be of at least −20° C. (−20° C. or lower) and preferably of at least −40° C. (−40° C. or lower). Common polypropylene based layers will not achieve such value.

These FPP selection tests should be performed on a film without fillers, of typically 0.5 mm.

Further, a FPP blend based layer having a cold foldability of −20° C., preferably −40° C. will keep its electrical insulation properties even in cold climates.

For ease of coextrusion, correction of viscosity can be performed by peroxide cracking or blending.

(Co-)Polyethylene: Polyethylene (PE) is well known and may be copolymerized with several comonomers to produce (co-) PE. Useful comonomers are vinyl acetate, acrylate (e.g. butyl acrylate, . . . ), alpha olefins (octene comonomers like for metallocene VLDPE with as commercial example Exact 0203); etc. Organic Block Copolymers (Infuse) are a particular type of (co-)PE.

Polar co-PE is a co-PE comprising at least 10% weight of polar comonomers like acrylates or vinyl acetates.

Non Polar co-PE is a co-PE comprising less than 10% weight of polar comonomers, e.g. VLDPE (PE co alpha olefins).

Functionalized (co-)Polyethylene: To improve adhesion to e.g. the front layer, like glass, or with layers (PA based layers, functionalized Polypropylene layers etc), or fleece or fabrics (glass, basalt, . . . based), the (co-)Polyethylene may be functionalized by copolymerization or grafting of reactive functional groups, provided with an unsaturation (double bond). Examples of reactive functional groups provided with an unsaturation (double bond) are: maleic anhydride (reactive with Polyamide, EVOH, glass, epoxy functionalities, amine functionalities, . . . of silanes or grafted to polyolefins), acrylic acids (reactive with Polyamide, EVOH, glass, epoxy functionalities, amine functionalities, . . . of silanes or grafted to polyolefins), glycidyl methacrylate (reactive with MAH grafted polymers, PET, acidic functionalities . . . ), vinylsilanes (VTMO) or other well known silanes like MEMO (reactive with glass, . . . ), . . . .

Polypropylene and other polyolefins can be functionalized in the same way to improve adhesion to incompatible layers by chemical reaction.

(Co-) Polyethylene Tie-layers are layers based on Functionalized (co-) Polyethylene.

(Co-) PolyPropylene Tie-layers are layers based on Functionalized (co-) PolyPropylene.

(Co-) PolyOlefine or TPO Tie-layers are layers based on Functionalized (co-) PolyOlefines.

Flexible PolyPropylene Tie-layers are layers based on Functionalized Flexible PolyPropylene, e.g. a blend of Functionalized PolyPropylene and possibly functionalized rubber.

Functionalized means that the polymer is modified by grafting or copolymerization reaction with an unsaturated reactive group. The reactive group may be any chemical group providing adhesion by chemical reaction with the polymer or surface it is designed to stick to. With polyamide or EVOH, the unsaturated reactive group will be preferably Maleic anhydride or an unsaturated acidic group (acrylic acid, . . . ).

PE-g-MAH means a PE grafted (g) with maleic anhydride. PP-g-MAH means a PP grafted with maleic anhydride.

Primer layer: A primer layer is an external layer of the backsheet, of which the purpose is to ease adhesion with other films or pieces (encapsulants, junction boxes, mounting hooks, fire barrier layers). A primer layer can be simply a surface treatment (like Corona or plasma) or a coextruded layer or layers, preferably polyolefin based layers, comprising possibly a functionalized polyolefin. For adhesion with EVA or VLDPE based encapsulants, a co-PE based primer layer (12b or 12b/12a or 12b/12a/13b) is very useful.

Heat Resistant Layer:
A layer comprising a resin having at least one DSC melting peak (ISO 11357-3) temperature greater than 170° C. (determined by curve), with as example Polyamide 12, 11 and 6. If modified with Polyolefins, homopolymer polypropylene will be preferred to keep the heat resistance.
In one preferred embodiment, the heat resistant layer is designed to provide a barrier effect to migration of additives from the encapsulants towards the (F)PP layers of the backsheet. The polymeric components of the heat resistant layers should therefore not be melted or only marginally be melted at lamination temperature (which is usually performed typically at a temperature between 145 and 155° C.) and will be selected on the base of DSC curves. As polymeric component of the heat resistant layers, it is preferred to use polymers having a DSC melting peak (ISO 11357-3) temperature of 5° C., preferably 10° C., even more preferably 20° C. superior to the PV module lamination temperature, which is typically between 145° C. and 155° C. and not more than 180° C. Fillers may advantageously be added, especially with a plate shape (clay, talcum, mica, kaolin, . . . ) to improve barrier effect to migration of additives. The heat resistant layer can be a multi-layer e.g. of the type A/B/A, on base of several heat resistant polymers (PA, PET, PEN, PBT, PC, EVOH, . . . ), with as example A=PA6/B=EVOH/A=PA6.
In one preferred embodiment, the heat resistant layer provides on base of its thickness and composition (polymers and fillers) an Oxygen Transmission Rate (OTR) of less than 100 cc/m².day.atm at 23° C. 50% relative humidity, more preferably less than 50 cc/m².day.atm at 23° C. 50% relative humidity, even more preferably of less than 25 cc/m².day.atm at 23° C. 50% relative humidity and even still more preferably of less than 10 cc/m².day.atm at 23° C. 50% relative humidity.
In another preferred embodiment, the heat resistant layer should not reduce the acetic acid permeability of the backsheet to less than 15 g/m².day, preferably not to less than 30 g/m².day, even more preferably not to less than 50 g/m².day and most preferably not to less than 50 g/m².day. PA6 is a useful polyamide to achieve such permeability.
Useful heat resistant layer, of which some can be combined to polyolefins tie-layers, and useful additives or dispersions (e.g. nanoclays, Imperm 105, Aegis MXD6, . . . ) to produce or to improve barrier layers, are described in “Les palstiques à effet barrière dans l'emballage” (F. Monfort-Windels Révision 2007). Imperm 105 is an excellent base material for a barrier layer within backsheets of this invention.
In another preferred embodiment, the heat resistant layer provides on base of its thickness and composition (polymers and fillers) a CO2 Transmission Rate (CO2TR) of less than 100 cc/m².day.atm at 23° C. 50% relative humidity, more preferably less than 50 cc/m².day.atm at 23° C. 50% relative humidity, even more preferably of less than 25 cc/m².day.atm at 23° C. 50% relative humidity and even still more preferably of less than 10 cc/m².day.atm at 23° C. 50% relative humidity. Imperm 105 (PA MXD6/nanoclay blend) is a useful base material for such heat resistant layer with excellent CO2 barrier properties. The nanoclays provide also excellent O2 barrier properties.
Heat resistant layers are more polar and more hygroscopic than usual PO based layers, meaning an higher dielectric constant and risk of blisters during module lamination (water vapor release). The thickness of the heat resistant layer should allow bringing the required barrier properties but should be lower than the thickness of the backsheet TPO layers together, preferably 1.5 time lower, more preferably 2 times lower, even more preferably 3 times lower and even still more preferably 4 times lower and best at least 5 times lower.

Transparent front layers used for this invention are based on glass or other transparent frontsheets (ETFE, PMMA . . . ), if required with adequate surface treatment like Plasma based treatment to graft adapted functionalities at the surface of the face of the front layer, coming into contact with Front encapsulant, if used.

When required (e.g. in the case of Crystalline Silicon cells based modules), front encapsulants used for this invention can be EVA based films or other films releasing detrimental products.

EVA is well known to release acetic acid. Such EVA film as upper adhesive layer is most generally a 0.46 mm thick film based on peroxide crosslinkable EVA (ethylene vinyl acetate), with a high fluidity (Melt Index (g/10 m; 190° C.; 2.16 kg) of more than 40) and comprising free silanes (i.e. not grafted before the lamination step of the PV modules). Useful EVA films formulation are e.g. described in WO 99/27588. They are well established as durable highly transparent adhesive layers. They are very useful to encapsulate thick crystalline Si PV cells (typically 250 μm) thanks to their ability to flow around the cells.

Other useful transparent polar co-polyethylene resins, useful to produce (layers of) encapsulant films, are EBA (Butyl Acrylate), EEA (Ethyl Acrylate), EMA (Methyl Acrylate) with an high amount of comonomer (higher transparency).

Usually crosslinking is preferred and obtained on base of peroxide (heat crosslinking) or by silane crosslinkers (humidity crosslinking) or on base of photoinitiators (UV crosslinking or curing). UV curing is an advantageous alternative (short cycles).

For heat crosslinking the encapsulant needs to contain a peroxide free radicals initiator (DHBP, TBEC, . . . Trade Name=Lupersol 101 or Lupersol TBEC). Usual multi-functional molecules (i.e. molecules provides with 2 or more unsaturations), also called crosslinkers, can be useful (e.g. allyl cyanurates like TAIC, TAC, . . . ) as they increase crosslinking density.

To reduce production of acetic acid, the front encapsulant can be of the structure EVA/VLDPE, i.e. a co-PE where the comonomers are alpha olefins (no generation of acids)/EVA or VLDPE/EVA or VLDPE/EVA/VLDPE, etc.

Especially when the layer of the multi-layer encapsulant which comes in direct contact with the glass front sheet is based on PE, especially LLDPE or VLDPE, the UV durability of the encapsulant may be improved, when UV absorber(s) are added in the layer which comes in direct contact with the glass front sheet and when such UV absorber(s) are highly compatible and durable within such layer. In this case, the layer which comes in direct contact with the glass front sheet will be able to shield the e.g. underlying EVA layer(s) from UV radiation from the sun.

It is preferred that the layer which comes in direct contact with the glass front sheet is based on a VLDPE or LLDPE with a density of more than 0.882 g/cm³ (more UV stable, low level of acidic by pro-ducts).

The layer which comes in direct contact with the glass front sheet may preferably contain a higher concentration of UV absorber than the other layer(s).

Useful UV absorbers are described e.g. in:
United States Patent Application 20080032078 A1 (Lazzari; Dario; et al.; Feb. 7, 2008)
EP 1892262 A1 (Highly compatible and non-migratory polymeric UV-Absorber)

Care is taken in the selection of all additives of all layers of the front encapsulant in matching the refractive indexes of all layers.

More generally, the structure of the encapsulant can be “comprising one or more polar co-PE based layer and one or more non polar co-PE based layer”.

The polarity of EVA (or of polar co-PE) allows avoiding exudation of several additives like silanes, peroxides, crosslinkers (TAC or TAIC).

A polar co-PE layer or layers are therefore desired for the purpose of additive retention and easier curing.

Following coextruded film structure is very useful: EVA based layer with cross-linking initiator/VLDPE based layer optionally with cross-linking initiator/EVA based layer with cross-linking initiator, each layer, especially the external layers, preferably comprising usual additives like thermal and UV stabilizers, adhesion promoters (silanes, possibly grafted), etc. The additives (cross-linking initiator, silanes, . . . ) are added to the layer self or are provided by migration from other layers. Peroxides are preferably added to thick layers (low shear and risk of premature crosslinking).

The less polar VLDPE layers can contain additives which are less compatible with EVA.

Alternatively, the structure can be “Functionalized (especially silane grafted, for adhesion to glass) VLDPE/EVA/Functionalized VLDPE”, or VLDPE (preferably glass side)/EVA. Highly durable UV absorbers can be added in the VLDPE layer in contact with glass to shield the EVA layer from UV radiation.

It has been also discovered that although the initial adhesion between polar co-PE, especially with a high amount of polar co-monomer, and non polar co-PE is poor, after cross-linking, the adhesion is much improved and sufficient.

The inclusion in the front encapsulant of a VLDPE layer will also reduce the phenomen called Potential Induced Degradation (PID) as such layer is nonpolar and, as a result, ionic mobility within such layer will be low.

When the front encapsulant is (partly) cured (e.g.), its crystallinity will be reduced and the film will become more transparent. Further, co-PE with lower melting temperature, and therefore lower crystallinity can be selected, with as result improved transparency and softness. As VLDPE is not so easily cross-linked as EVA, it is better to use a VLDPE with an higher DSC peak melting temperature than EVA, e.g. of more than 65° C., preferably more than 75° C.

The rear encapsulant can be EVA but may be based on material with low release of detrimental product, e.g. on base of (co-)PE where the comonomers are alpha olefins (no generation of acids), even if such (co-)PE generally lead to slightly less transparent films (back-layer application).

Because the backsheet of this invention can be much softer than usual backsheets (TPT), it is possible to use a rear encapsulant, e.g. on base of VLDPE Exact 0230 (DSC Tm=97° C.; density=0902; tensile Emodulus of 90 MPa), possibly as integrated adhesive, which is stiffer than EVA (tensile Emodulus of 15 MPa at 20° C.). Crosslinking of the rear encapsulant can advantageously be avoided because the melting temperature of the rear encapsulant (in this case based on VLDPE with a DSC melting peak temperature of 97° C. (ISO 11357-3)) is above the temperature encountered in the field. Partly crosslinked can be applied by silane crosslinkers. Most useful VLDPE (blend) have a DSC melting peak temperature ranging from 65° C. to 110° C., preferably from 75° C. to 100° C.

Of course, VLDPE based front encapsulants are the best option to avoid the risk of (local) corrosion and PID. To improve adhesion with glass and PV cells, such encapsulants will be provided with silanes adhesion promoters, possibly copolymerized or grafted to the PE backbone. Most useful VLDPE are stiffer than EVA. Compensation is provided by the softer backsheets of this invention.

“Mainly TPO based backsheets possibly including a rear encapsulant layer” are described in patent applications PCT/EP 2010/004335 (“Photovoltaic modules with Polypropylene based backsheet”), PCT/EP2009/000665 (“Photovoltaic modules and Production Process”), and in European patent application No: 10007553.0 (“Photovoltaic Modules using an adhesive integrated Heat Resistant multi-layer Backsheet”). The backsheets described in those applications, of which the text is incorporated by reference to the present description, are all useful for the present invention.

Cost effective backsheets comprise:
i. Possibly a tie-layer in contact with the backside (electrical back-contact, . . . ) (13b) of the PV cells, on base of a functionalized (e.g. by grafting or copolymerizing a functional group like a silane or a maleïc anhydride or an acrylic acid, or a glycidyl methacrylate, . . . ) co-polyethylene, such functional group selected to achieve a good adhesion to the backside (electrical back-contact, . . . ) of the PV cells. Further, the (co-)PE is preferably on base of alpha olefin comonomers (no generation of acids) or of OBC.
ii. Possibly a preferably soft (co-)polyethylene based layer or layers (12a) selected (softness, melt index, thickness) to achieve a good encapsulation of e.g. thick crystalline silicon cells. The thickness and fluidity will be increased in case of thick PV cells. The (co-)PE is preferably on base of alpha olefin comonomers (no generation of acids). The softness may be increased to limit mechanical damages to thin and brittle PV cells, like crystalline PV cells of low thickness (<200 μm) and to their interconnection (weak solders of e.g. back contact solar cells). OBC co-PE is a useful material as component of this layer to increase softness (especially at low temperature). Lamination temperature is adapted to the melting temperature of the encapsulant film and vice versa, i.e. pressure is applied only when the polymers are melted. This layer can be multi-layer and the layers facing the backsheet are preferably opaque to protect the heat resistant layer from light. Layer or layers facing the cells may be left transparent to limit risk of opaque material flowing above the PV cells during module lamination.
iii. one or more connecting layers (12c-12c-12d) allowing achieving good adhesion between the rear encapsulant like EVA or like co-polyethylene based layer(s) and the mainly FPP based layer(s)
iv. a mainly Flexible PolyPropylene based layer (11), being possibly a multi-layers layer comprising possibly at least one layer with higher heat resistance (e.g. a layer on base of a homopolymer PP blend and/or provided with glass fibers or glass beads) to keep mechanical integrity during lamination temperature (typically 150° C.). PA or PA/PP or PA/PE blends, usefully with glass fibers and/or beads, based layer may also be included (with the help of intermediate polyolefin based tie-layers) for such purpose. Such layers are selected in thickness and in composition to allow preferably for a high acid permeability.

Layer i and/or ii may be (partly) cross-linked e.g. by humidity e.g. in use and the co-PE base material of such layers will be equipped (reactive extrusion) with silane crosslinkers (grafted silane like MEMO or VTMO). Such layers may also be multi-layers layers comprising layer(s) without silane crosslinkers and at least one of such layers is provided with a condensation catalyst.

Connecting layers are provided between the mainly Flexible PolyPropylene based layer and the rear encapsulant layer(s), typically EVA, and can be:
option 1) a TPO mixture based layers or layer creating an interpenetrated network of VLDPE and PP (based e.g. on a mixture of VLDPE, FPP reactor blend and PP elastomer). Such layers may be partly crosslinked to improve inter-layer adhesion
option 2) a 3-layer reactive system, being e.g. “a (co-)PE-g-MAH based tie-layer (or another adequately Functionalized (co-)Polyethylene based tie-layer)/a PA or a EVOH based film layer or a Polyester based film layer (PET, PBT, . . . )/a a thin PP-g-MAH based tie-layer, preferably in blend with (functionalized) rubber like EPR rubber” to increase permeability to detrimental by-products like acetic acid through this layer.

Combination or blends of PA (layers) and EVOH (layers) are further possible and useful when improved oxygen barrier properties are required.

The PA based layer can be further based on a blend of PA/(F)PP or PA/PE, where the (F)PP or the PE is partly functionalized, for good adhesion to and dispersion into the PA phase, with e.g. maleic anhydride (by reactive extrusion). Blending with (F)PP and/or PE reduces the dielectric constant of the layer (reduced hygroscopicity), the price and increases oxygen permeability of the backsheet, which may be useful for building passivated oxide layers (corrosion protection) within the PV module and/or for bleaching of encapsulant films or layers like EVA based encapsulant films or layers.

To achieve a high permeability to oxygen (separation inner-layers (within the PV module)), preferred polyamide are polyamides with a longer CH2 sequence than for Polyamide 6. A useful polyamide is polyamide 12.

Other tie-layers may be used (e.g. PE co Glycidyl Methacrylate PE-GMA), especially with PET or PBT. Such layers are preferably microperforated to increase permeability to by-products (being understood than the dielectric FPP layers are not).

Other combination can be derived like: micro-perforated PE-GMA based tie-layer (i)/microperforated Polyester based layer (ii)/PE-GMA based tie-layer/PP-g-MAH based tie-layer/FPP based layers, being understood that the microperforation is limited to layers (i) and (ii).
option 3) a 2-layer reactive system, being “a PE-GMA copolymer based layer/a PP-g-MAH based layer”. See for more details US 2010/0108128 A1 (coextruded, multilayered polyolefin-based backsheet for electronic device modules).

To reduce, in a general way, the risk of corrosion, a polymer improving the oxygen barrier of the mainly polyolefin based backsheet is preferred.

Option 2, in particular inclusion of a polyamide based layer (12c), is preferred to improve the heat resistance of the PV module package (avoid the risk of perforation of the backsheet by the bus bars and solder points during module lamination) and avoid migration of components (e.g. peroxides) of the encapsulants into the FPP layer(s) and possibly reduce oxygen and CO2 permeability.

To improve heat resistance and dimensional stability during lamination, to reduce mismatch of thermal expansion coefficient between layers, especially FPP and PA based layers), to increase stiffness (especially of FPP layers) while reducing the CLTE, to reduce lateral flow during module lamination (under pressure and heat) and poor adhesion to the front layer (glass, . . . ) of the front encapsulant at its edges and corners, and to improve reaction to fire of the backsheet, glass fibers or other mineral particles (talcum, flame retardants . . . ) may be added in one or more layers of the backsheet, preferably at least in the FPP main layer.

The FPP based layers without glass fibers/beads are soft (typically at least 4 times softer than PP, i.e. a Emodulus of 400 MPa or less) and have indeed a high coefficient of linear thermal expansion (CLTE) of typically 120 à 200 10⁻⁶ m/m K. at 20° C. Addition of glass fibers/beads in FPP based layers allows a reduction of CLTE typically of a factor 1.5 to 2. Addition of glass fibers/beads in FPP based layers increases their Emodulus typically of a factor 1.5 to 3. Acetic acid permeability is anyway kept by such addition and low temperature contraction forces are still by far lower than for common Polypropylene, especially if filled.

Addition of typically 5 to 15% of fibers or more, especially glass fibers, in FPP based layers reduces surprisingly the tendency of the e.g. EVA based front encapsulant to be much expelled from the PV module, during and after module lamination (typically 150° C. 15 minutes and under 1 bar pressure), at the edges and corners of the PV module, leading to adhesion defects of EVA to the front layer (especially glass) in these critical areas (edges and corners). The same effect is achieved with a lower amount of (glass) fibers provided other fillers are added like glass beads.

Fillers having a plate shape, like talcum, mica, etc., are useful to reduce the water vapor permeability and oxygen transmission rate if needed, but will also reduce acetic acid permeability.

Glass fibers may in some extent increase acetic acid permeability and water vapor permeability. The glass fibers are surface treated especially by amino-silanes and the FPP contains preferably a functionalized PP, e.g. a MAHgrafted PP to improve adhesion of the silane treated fibers to the FPP matrix (amine-MAH reaction).

The length of the glass fibers is typically between 300 and 1000 μm. For softer compositions, a higher length is advantageous and should usefully be above the critical fiber length (required minimum glass fiber length, for a given diameter of the fiber, for achieving maximum transfer of stress (i.e. achieving tensile strength of the fiber) from the matrix to the fibers) and can be easily defined by the man skilled in the art, in combination with the right amount of coupling resin.

A mixture of (e.g. glass) fibers and glass beads or other 2-D (plates) or 3-D (beads) fillers is also very beneficial to improve dimensional stability and increased the E-modulus. The advantage of a mixture of e.g. glass fibers and e.g. glass beads or talcum, mica, clays, etc. compared to the same amount of glass fibers alone is the improved processability (extrusion) of the polymer blend. A reduction in anisotropy can be achieved in such a way.

The last layer of the backsheet, facing the junction box, may be without glass fibers, to avoid water ingress risk (capillarity along the glass fibers).

Further, to improve thermal stability (retention of mechanical properties during aging at elevated temperature, i.e. e.g. to achieve a relative thermal index or endurance of (layers of) the backsheet of more than 90° C., preferably of more than 105° C., anti-oxidants are required.

Polyamides with better intrinsic thermal stability like PA 11 or PA 12 are useful but expensive and have poor oxygen barriers.

A cost effective very useful layer (heat resistance—reduced risk of perforation) is a Polyamide 6 based layer. Poor thermal stability of Polyamide 6 and sensitivity to humidity (meaning a.o. very poor dielectrical performances after water take-up) and UV aging don't allow the use of PA 6 as base component of backsheet alone. It has been discovered that a PA 6 based layer may be used when protected by layer(s) with good electrical properties, water barrier properties, UV and thermal durability and cold impact mechanical properties. A very effective protection and dielectric layer is a preferably opaque, UV stabilized and heat stabilized FPP based layer(s).

Other UV sensitive barrier layer may benefit of the UV protection of such FPP based layer(s), like polyamide MXD6, Selar PA, etc. Protection from light from the front side is provided by coextruded tie-layer (12b) and primer layers (12a), which are opacified with pigments.

Blending the polyamide with polyolefins (using preferably compatibilizing resins) allows also for a reduction of the dielectric constant of the polyamide. A reduced dielectric constant means a better resistance to the phenomen of partial discharge, as the electric field around defects will be reduced. This means that thinner layers may be used for the same System Voltage rating of the backsheet.

Adhesion of the (F)PP based layer(s) to the PA based layer(s) is preferably provided by a PP based tie layer (e.g. PP grafted MAH) by coextrusion. The PP based tie layer preferably comprises rubbery material (EPR, EPDM, VLDPE, Elastomer PP, . . . , advantageously functionalized) to improve permeability to acetic acid and softness at low temperature.

The heat stabilizer package of the (F)PP based layer(s) preferably comprises a phenolic anti-oxidant, and a phosphite or phosphonite and more preferably a phenolic anti-oxidant, a phosphite or phosphonite and a sulfur compound (thiosynergist). Classical (non low gas fading) very effective anti-oxidants like Irganox 1010 may be used to stabilize the (F)PP based layers as the heat resistant layer e.g. a polyamide based layer acts as barrier against the migration of the peroxides or photoinitiators from encapsulation films towards the (F)PP based layers and degradation by generated free radicals.

Further the (F)PP layers are UV stabilized with HALS (see Plastics additives handbook—fifth edition for further details).

When thiosynergists are used, the HALS is selected from low reactive HALS (NOR-HALS or HALS with a good steric hindrance) to avoid neutralization of the thio-synergist anti-oxidant. The Hals is preferably added to the melt in a master batch form to limit reactions with thiosynergists.

Useful Anti-oxidants a.o. to improve the thermal stability of Polypropylene are described in Plastics Additives Handbook 5^{th} edition, p. 40 and following: A thermal stability of PP plaques (1 mm) of up to 80 days (11 weeks) at 150° C.—see p. 54—can be achieved on base of combination of phenolic, phosph(on)ite and thiosynergist anti-oxidants. Taking into account an activation energy of 106 kJ/mole, this means a RTE of typically 120° C. (20.000 hours stability at 120° C.) or more. When the FPP based layer is highly filled, araldite 7072 may be added to the formulation to further improve heat stability.

On the other hand (see p. 81), Polyamide 6 plaques (1 mm) can't achieve a long term thermal stability (20.000 hours) of even 100° C. 90° C. may well be achieved.

It has been discovered that a backsheet comprising a polyamide a.o. a polyamide 6 based layer (or layers) may achieve a RTI or RTE (i.e. typically keeping more than 50% of the initial tensile strength after 20.000 hours) of 105° C., even 110° C. and even 115° C. when such PA based layer(s) is (are) combined with highly heat stabilized FPP based layers (and PP based layers) designed a.o. by addition of fillers in such a way that they dominate in the tensile properties of the backsheet.

The present invention defines several ways to achieve dominance of FPP based layers (and PP based layers) in the tensile strength of the backsheet.

Layers are preferably designed in such a way that the tensile strength and/or the Emodulus (tensile test according Iso 527-3) of the FPP and PP based layers (including the PP tie layer(s)), multiplied by their total thickness is not less than 50%, preferably not less than 75%, most preferably not less than 100% of the tensile strength and/or Emodulus of the polyamide based layer(s) multiplied by its (their) total thickness.

A useful and more general design rule is that the Sum, for all TPO layers of the backsheet, of their E-modulus multiplied by their thickness, is not less than 50% preferably 75%, more preferably 100% of the Sum, for all Heat Resistant layers of the backsheet, of their E-modulus multiplied by their thickness.

In such a way, the contribution to tensile strength of the (F)PP based layers can be enough to allow keeping a tensile strength of at least 50% of the initial value of the backsheet, even when the polyamide based layer(s) have lost nearly completely their mechanical properties. In other words, the polyamide based layers have a limited or no reinforcing effect in the backsheet.

It is possible to increase the E-modulus of the (F)PP based layers by addition of fillers (talcum, clay, kaolin, glass beads, mica, (glass) fibers, magnesium hydroxide, aluminium hydroxide, calcium carbonate . . . or combinations) and/or by a lower amount of rubber in the FPP blend.

It is possible to reduce the E-modulus of the polyamide based layers by addition of plasticizing/impact modifying resins or rubbers or plasticizers or combinations thereof.

Impact modification of Polyamide is usually provided by blending with functional co-PE and co-PE (PEcoButul Acrylate, . . . ), which reduces PA E-modulus.

Several means are possible to reduce the Tensile strength (by reduction of the elongation at break) of the Polyamide based layer(s), such as higher filler loading (talcum, glass beads, mica, glass fibers, magnesium hydroxide, aluminium hydroxide, calcium carbonate . . . and combinations).

It has in particular been discovered that by increasing the E modulus and tensile strength of the thermally stabilized FPP layers, by addition of glass fibers or other fillers (glass beads, talcum, mineral fibers . . . ) in the FPP layers, i.e. by increasing the relative contribution of the FPP based layer(s) to the tensile strength of the PA/FPP based backsheet, the loss of tensile strength can be kept limited to less than 50% during 20.000 hours at a temperature of 105° C., even 110° C. and even 115° C.

More specifically, it has been discovered that the several PP and FPP based layers of the backsheet should be filler reinforced in such a way that they achieve a maximum tensile strength for an elongation which is closed to the yield point of the polyamide layer(s), i.e. for an elongation of typically 10% (between 5% and 30%). This means practically that the FPP layers are stiffened and their E-modulus come closer to the E modulus of the polyamide layers of the backsheet.

It is anyway preferred to select FPP layers having a E-modulus as close as possible to the E-modulus of the Polyamide layer(s) while still having a high content of rubber (better acetic acid permeability, cold impact properties, stress relaxation properties) in the FPP material. Stiffness and high rubber content are of course contradictory, but very useful.

Adding fillers like glass fibers to the composition of the FPP layer(s) with high rubber content is therefore preferred. Addition level of glass fibers will be typically between 2 and 50% weight, preferably 5 and 40% weight, more preferably 8 to 30% weight of the FPP layers. Addition of talcum and other plate-like fillers is possible but not always preferred because of a negative impact on permeability (reduced permeability to acetic acid). Such fillers improve anyway the oxygen and water vapor barrier of the layers of the backsheet. Addition of glass beads to replace partly glass fibers is useful for the processing (extrusion).

As the heat resistant layer(s) is/are usually more hygroscopic than TPO based layers, it is, for this reason also, preferred to have a lower total thickness of heat resistant layers than of TPO layers.

In is advantageous that the total thickness of the PolyPropylene layer or layers (PP, FPP, PP tie-layer) or more generally that the total thickness of the TPO layers is higher than the total thickness of the Heat resistant layer or layers, preferably 1.5 time higher, more preferably twice higher, even more preferably 3 times higher, even still more preferably 4 times higher.

Addition of fillers e.g. glass fibers to the polyamide layer(s) leads to a reduction of the tensile strength and elongation of the Polyamide layer(s). By such addition, the contribution of the Polyamide layer(s), to the tensile strength of the backsheet, is reduced. A better relative retention after heat aging of tensile strength of the backsheet can therefore (partly) be achieved in such a way. Indeed, the mechanical properties of the polyamide layer being initially reduced (poor initial elongation), by addition of the fillers, like glass fibers, the relative loss of tensile strength after aging of the backsheet will be lower, being understood that the FPP based layers keep their mechanical properties thanks to their excellent thermal stability as a result of addition of suitable anti-oxidants.

As already stated, adjustment of the thickness of each layers is of course the easiest approach to limit or avoid the reinforcing effect of the Polyamide layers. This is especially useful when polymer with high oxygen barrier properties are used for the heat resistant layer, like polyamide MXD6, possibly combined with fillers (Imperm 105 from nanocor).

Inorganic flame retardants (Magnesium or Aluminium Hydroxide, . . . ) are useful to reduce the flame spread index (ASTM E162) of the backsheet.

Further such fillers (more generally fillers having reactive hydroxyl (OH) groups available), may have a positive impact on (increase) acetic acid permeability. More precisely, they improve extraction of acetic acid from the encapsulant films as they are able to react with migrated acetic acids, keeping a high diffusion gradient between encapsulant films and backsheet. It is preferred or at least useful to add such fillers in layers of the backsheet which are close to or in contact with the encapsulant films.

Pigments, especially TiO2, are useful, in all layers, to increase the solar reflectance of the backsheet and to shield light sensitive inner-layers (barrier layers) within the backsheet from light. Other opacifying pigments and light absorbers are useful for such last purpose too.

To achieve good adhesion with co-polyethylene based encapsulant layers, the polyamide based layer is preferably also coextruded at the cells facing side with a (co-)PE tie layer. Such layer provides also good adhesion to the aluminium frame if such is used.

To avoid premature degradation of the tie-layers, the Polyamide layer will preferably not be stabilized with classical Cu/I based Polyamide stabilizers (Cu is a thermal degradation catalyst). Such stabilizers are the only well known to provide to polyamide a RTI of 105° C. or more. Such anti-oxidant package is further of the type “low gas fading (no phenolic included)” but the Cu will catalyze polyolefin thermal degradation and the Iodine (I) will lead, especially after reaction with migrated peroxides, to hydrolysis of the bonds between the PA layer and the tie-layers. Delamination is observed after a short period of time (typically <1 week immersion in water 80° C.).

A useful approach can be to encapsulate the Cu/I stabilized PA based layer between two non Cu/I (e.g. Nylostab S-EED stabilized) stabilized PA based layers, which will then provide the adhesion with the tie-layers of the backsheet, with less catalytic degradation by Cu.

Adapted anti-oxidant package needs to be selected especially for the PA based layers, more especially the one in contact with the tie-layer (12b) of the backsheet, acting as barrier layer(s) against radicals migration (crosslinking agents) and for the (co-)PE tie layer (12b) coming in contact or submitted to the radicals migrated from the encapsulant layers (EVA . . . comprising radical generating products).

Classical phenolic anti-oxidants lead to severe discoloration after reaction with migrated peroxides when the PV modules are submitted to the Damp Heat Test (aging 1000 hours at 85° C., 85% Relative Humidity). To avoid discoloration as a result of the reaction of anti-oxidants of the backsheet with activated migrated radicals initiators (peroxide or photo initiators . . . ) from the encapsulant layers and by further hydrolysis reactions by humidity and heat (Damp Heat Test i.e. climatic test at 85° C., 85% relative humidity), low gas fading anti-oxidants are preferred especially in the Polyamide and (co-)PE based layers (the most submitted to radical attack by migrated radicals from the encapsulant films). Such anti-oxidants are secondary anti-oxidants like phosphites or phosphonites, hals and specific phenolic anti-oxidant of the type low gas fading, like Adeka AO 80 supplied by Adeka or Irganox 245 supplied by BASF and blend thereof, but they don't provide a RTE of 105° C. to polyamide or at least the achieved RTE is lower than with Cull systems. Compensation is required.

Other very suitable anti-oxidants for Nylon are the “Nylostab S-EED” family (supplied from Clariant), possibly in blend with phosphites and other Hals. Such anti-oxidants and blend thereof provides a good heat aging of the polyamide layer at only 90° C. or slightly more. The polyamide layer will achieve therefore a RTI of only 90° C. or slightly more.

A multi-layer PA6 based layer with a core or main PA6 based layer stabilized with a Cu—I based anti-oxidant system and at least one external layer (in contact with the functionalized PE based tie-layer) stabilized on base of another type of anti-oxidant like e.g. “Nylostab S-EED”, will achieve a RTI of more than 105° C. Useful Cu—I based anti-oxidant system are sold by e.g. Brueggemann under the trade name Bruggolen® e.g. TPH 6010. In such a case, the (co-)PE tie-layer is protected from degradation by the Cu—I system (non Cu—I based stabilized intermediate-separation Polyamide layer).

Anti-oxidants and Hals are further described in Plastics Additives Handbook.

As the thermally stabilized FPP based layers, especially layers without fillers, provide excellent electrical insulation and have a RTI of 105° C. or more, a backsheet with a system voltage (IEC 60664-1:2007) rating of at least 600 VDC can be achieved at a RTI rating of 105° C. or more by the inclusion into the backsheet of thermally stabilized FPP based layers of a thickness of only 100 μm or a bit more.

Heat Stabilized (F)PP based tie-layers contribute also to electrical insulation and have a RTI of 105° C. or more.

By coextrusion of heat stabilized FPP based layers with a thermally stabilized Polyamide 6 layer, the system voltage (IEC 60664-1:2007) of the obtained backsheet will be increased to possibly 1000 VDC, but only for a RTI rating of 90° C. or only slightly more (<105° C.) because the Polyamide 6 based layer is not thermally stable enough at 105° C. to be considered as providing electrical insulation for a 105° C. RTI rating or more.

The combination of heat stabilized FPP based layers and heat stabilized PA 6 based layers is anyway very useful, because PV modules requiring a system voltage of 1000 VDC are used for solar farms where a RTI rating of 90° C. is generally sufficient and PV modules requiring a RTI rating of 105° C. or more are used mainly for little systems (roof top—building integrated) requiring a lower system voltage than 600 VDC.

Because Flexible PolyPropylene is an excellent dielectric and is flexible compared to PET, it is possible to produce thick backsheets (typically 0.6 mm) with a system voltage of 1500 VDC or more. In such thickness PET is very stiff and difficult to process without defect (poor lamination) as result of stresses on PV cells.

To avoid undesired reactions of the anti-oxidants during extrusion, it is useful to add the anti-oxidants to the polyamide with the help of a polyolefin based master batch, preferably a functionalized polyolefin based master batch.

It is preferred that the co-PE based layers of the backsheet (facing the encapsulant) are very opaque (addition of a high loading of TiO2) to reduce discoloration.

It is preferred to use a rear encapsulant which is not crosslinked and based on VLDPE and/or OBC co-PE. Compared to EVA (E-modulus of 15 Mpa), VLDPE, and even OBC, of sufficient DSC melting peak (ISO 11357-3) temperature (i.e. not requiring crosslinking), are stiffer than EVA, leading to higher stresses of PV cells under e.g. snow load. VLDPE exact 0230 has a DSC melting peak temperature of 97° C. and a E-modulus of 90 MPa (density 0.902), while Exact 8230 has a DSC melting peak temperature of 73° C. and a E-modulus of 36 MPa (density 0.882 g/cm³). OBC of sufficient DSC melting peak temperature have a E-modulus of around 30 à 40 MPa. To compensate for the higher E-modulus of the rear encapsulant, the backsheet, which is combined with such stiffer encapsulant, should be softer than usual backsheet like TPT base backsheet (E-modulus of 3500 MPa; CLTE at 20° C. of 30 10⁻⁶/K). This is the case of backsheets of this invention.

It has to be observed that a figure of merit for Backsheet is the E-modulus*CLTE, which is at the origin of stresses during thermal cycli.

i. PP=1600*80=128.000
ii. TPT: 3500*30=105.000
iii. FPP-Glass fiber reinforced <100.000

To solve the problem of locally high concentration of detrimental (by-) products leading to blistering and/or corrosion, the invention provides a possibly multi-layer based electrical insulating film which is highly permeable to such detrimental products. A convenient way to achieve the high permeability is micro-perforation of the film. Classical well known films are the so called “Tedlar®/PET/Tedlar®” or “PE/PET/PE”, where Tedlar® is a surface treated PVF film and PE is a PolyEthylene (possibly copolymerized with a low amount of Vinyl Acetate (<10% weight VAc)) based film.

Preferably the core of the film is based on Polyamide, like polyamide 6, 11 or 12 or blends of polyamide with preferably (flexible) Polypropylene or Polyethylene, functionalized for compatibility with polyamide. To improve O2 exchange within the PV module, PA11 or PA12, particularly in blend with Polyolefins, is preferred.

Preferably, such electrical insulating film is adhered (embedded) to adjacent layers on base of material which doesn't release significantly detrimental (by-) products. A possibility is a VLDPE based encapsulant (functionalized and possibly peroxide crosslinked).

A preferred structure (embedded electrical insulating film) is produced by coextrusion and is as follows:
(Co-)PE tie-layer with similar composition as the optional (Co-)PE tie-layer (13b) of the backsheet, coming into direct contact with the backelectrode of the PV cells (4). The (co-)PE is preferably on base of alpha olefin comonomers (no generation of acids).
soft (co-)PE with similar composition as the optional (co-)polyethylene based layer (12a) of the backsheet. The (co-)PE is preferably on base of alpha olefin comonomers (no generation of acids). The softness may be increased to limit mechanical damages to thin and brittle PV cells, like crystalline PV cells of low thickness (<200 μm) and to their interconnection (weak solders of e.g. back contact solar cells). OBC co-PE is a useful material as component of this layer to increase softness (especially at low temperature).
(Co-)PE tie-layer with similar composition as the (Co-)PE tie-layer (12b) of the backsheet, coming into direct contact with the PA based layer described next. The (co-)PE is preferably on base of alpha olefin comonomers (no generation of acids).
PA based layer or PA/(F)PP or PA/PE blend based layer where the Polyolfin ((F)PP or PE) is functionalized for good adhesion to and dispersion into the PA phase, e.g. with maleic anhydride and where the PA is preferably on base of PA11 or PA12.
(Co-)PE tie-layer with similar composition as the optional (Co-)PE tie-layer (12b) of the backsheet
soft (co-)PE with similar composition as the optional (co-)polyethylene based layer (12a) of the backsheet. The (co-)PE is preferably on base of alpha olefin comonomers (no generation of acids). The softness may be increased to limit mechanical damages to thin and brittle PV cells, like crystalline PV cells of low thickness (<200 μm) and to their interconnection (weak solders of e.g. back contact solar cells). OBC co-PE is a useful material as component of this layer to increase softness (especially at low temperature).
(Co-)PE tie-layer with similar composition as the optional (Co-)PE tie-layer (13b) of the backsheet being a functionalized (co)PE based tie-layer for adhesion to the conductive ribbon.

The invention will be illustrated further by reference to the attached drawings which are not meant to restrict the scope to the specific embodiments shown. Other combinations of the preferred features than those shown are also possible and advantageous. It should be appreciated that for simplicity and clarity of illustration, elements shown in the figures have not necessarily been drawn to scale.

FIG. 1 shows a cross section of a PV module showing:
a front layer like a glass plate (typically a 3.2 mm low iron tempered glass) (1)
a transparent upper adhesive layer (2), e.g. a film of EVA Vistasolar 486.10, 0.46 mm or a multi-layer film of a structure comprising apolar and polar co-PE layer(s), like EVA/VLDPE/EVA, comprising radicals initiators (like peroxides or UV photoinitiators) and/or grafted silanes crosslinkers to achieve crosslinking (by heat or UV or humidity) during or after lamination and comprising usual additives (HALS, anti-oxidant, possibly UV absorbers, possibly anti-acid, possibly crosslinkers of the type TAIC or multi-acrylates etc.) or VLDPE based encapsulant, possibly only partly or not crosslinked but having an higher Emodulus than EVA based encapsulant.
PV cells (4), which may be PID sensitive
a rear encapsulant (5) (EVA or a tie-layer (13b)/soft co-PE layer (12a)).
a mainly FPP backsheet (11), preferably with connecting layers (12), preferably comprising a heat resistant O2 barrier layer (12c), having preferably a lower rigidity than TPT backsheet
a interconnecting conductive ribbon (6)
an insulating film (7)
a local zone of risk of corrosion (66), where detrimental (by-)products can be trapped, e.g. acetic acid, especially when film 7 is embedded in EVA films.

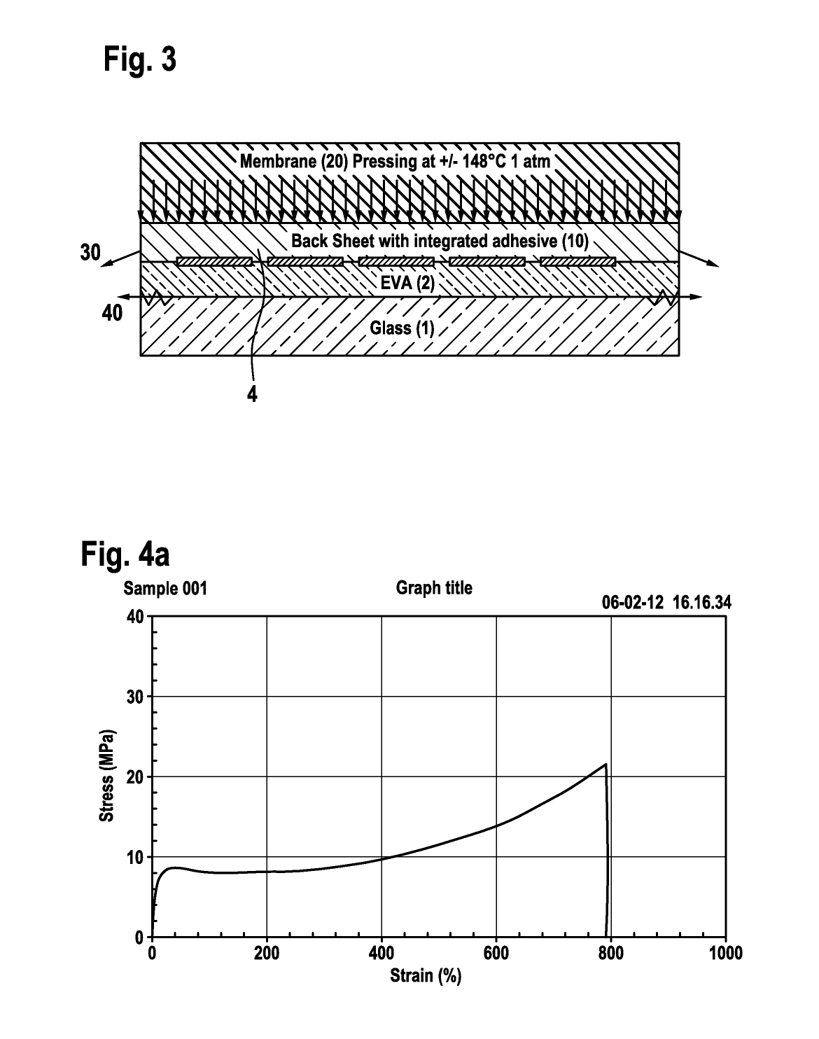

FIG. 2 shows a cross section of a PV module with
i. a front layer glass plate (1)
ii. a transparent upper adhesive layer (2), e.g. a film of EVA Vistasolar 486.10, 0.46 mm or a multi-layer film of a structure comprising apolar and polar co-PE layer(s), like EVA/VLDPE/EVA, comprising radicals initiators (like peroxides or UV photoinitiators) and/or grafted silanes crosslinkers to achieve crosslinking (by heat or UV or humidity) during or after lamination and comprising usual additives (HALS, anti-oxidant, possibly UV absorbers, possibly anti-acid, possibly crosslinkers of the type TAIC or multi-acrylates etc.) or VLDPE based encapsulant, possibly only partly or not crosslinked but having an higher Emodulus than EVA based encapsulant.
iii. active layers (4)
iv. e.g. a rear encapsulant (5) (EVA) and a mainly FPP backsheet (11) preferably with connecting layers (12) or a mainly TPO based backsheet with e.g. integrated adhesive (10) comprising:
   1. a functional (co-)PE tie-layer (13b) with good adhesion to active layers (4) back-electrode or back barrier or back primer coating and to adhesive layer (2),
   2. if desired, a possibly multi-layer encapsulating layer (12a), having appropriate softness and melting temperature to limit stresses on active layer(s) (4), adequate viscosity and thickness to encapsulate possibly thick active layer(s) like crystalline silicone PV cells (4) and preferably sufficient opacity to protect light sensitive heat resistant layer(s) (12c).
   3. if required connecting layers (12b) (12c) (12d) . . . .
   4. a backsheet (11) e.g. based on a multi-layer (F)PP based layer.

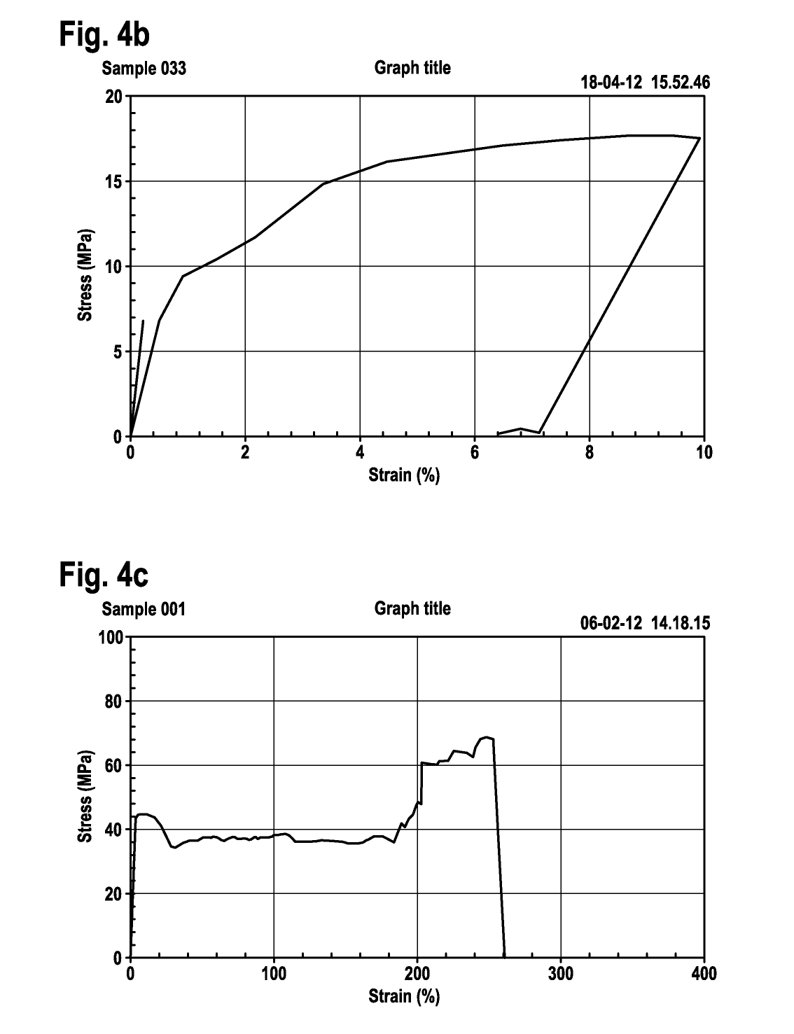

FIG. 3 shows a cross section of a PV module being laminated in a classical membrane (20) press:

The cross-section shows:
a glass plate (typically a 3.2 mm low iron tempered glass) (1)
a co-PE based front encapsulant (2), e.g. a film of EVA Vistasolar 486.10—0.46 mm, especially a film with a low melting peak temperature (typically <100° C.) and high fluidity (Melt Index >30 g/10 minutes; 190° C.; 2.16 kg).
PV cells (4)
An adhesive integrated backsheet (10) or rear EVA (5)—Backsheet (11), preferably with connecting layers (=10).
A membrane (20) pressing the several layers (1, 2, 4, 10) together at a temperature of +/−145° C., with a pressure between 0.5 and 1 bar, and leading to lateral flow (see arrows 30) of the backsheet (10) and mainly of the front encapsulant layer (2), with as result poor adhesion (40) between glass (1) and front encapsulant (2): Under such pressure and temperature, the front encapsulant adhesive (2) is expelled (30-40) and ripped (40) from the glass plate (1) at the edges and corners of the PV module. Such problem is reduced when the Backsheet (11 or 10), especially FPP layers, comprises fillers, especially glass fibers, especially of typically from 5 to 1000 μm length ore more, preferably 200 to 1000 μm length.

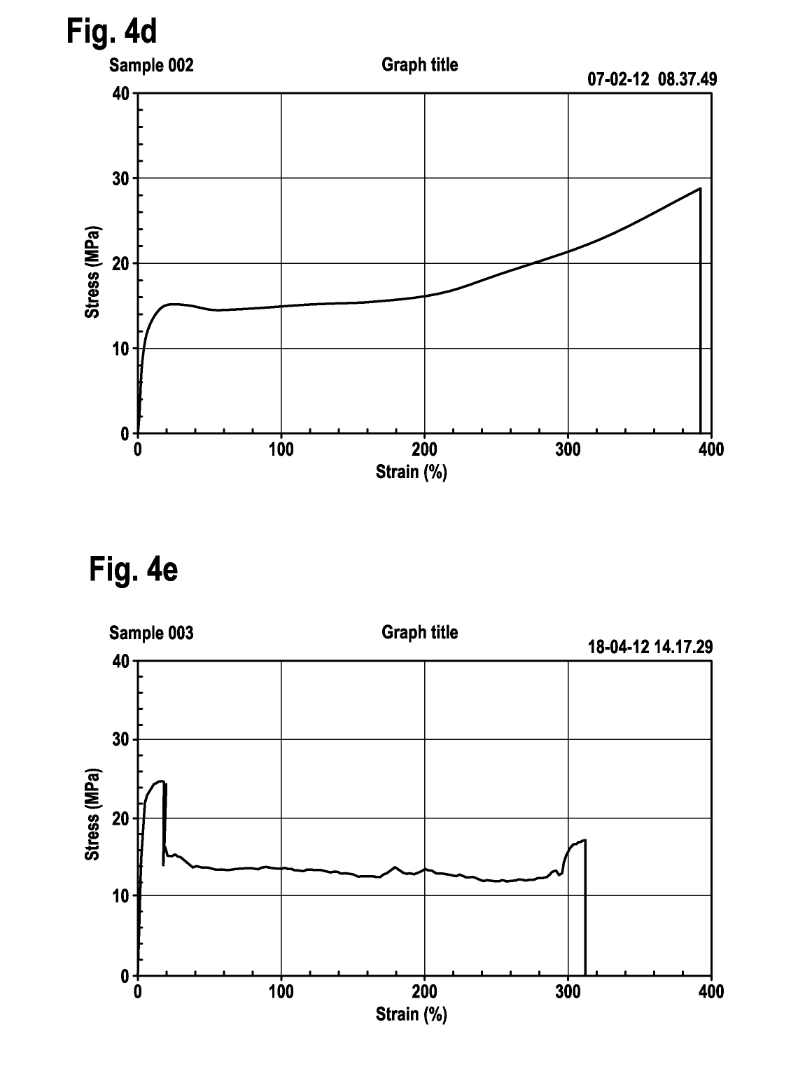

FIGS. 4a) to 4e) show tensile strength graphs of:

FIG. 4a) a Flexible PolyPropylene based layer

FIG. 4b) a layer based on the same Flexible PolyPropylene as 4a) but reinforced with glass fibers (12% glass fibers) in such a way that the FPP layer has a much higher tensile strength contribution to the backsheet at typically 10% deformation (Polyamide yield zone)

FIG. 4c) Polyamide 6

FIG. 4d) A multi-layer structure: 50 μm PEgMAH/75 μm Polyamide 6/25 μm PP gMAH/200 μm Flexible PolyPropylene (material from 4a).

FIG. 4e) A multi-layer structure: 50 μm PEgMAH/75 μm Polyamide 6/25 μm PP gMAH/200 μm Glass reinforced Flexible PolyPropylene (material from 4b).

In FIG. 4d), the polyamide layer acts as reinforcing layer. When such layer loses its mechanical properties after heat aging, the full backsheet has poor mechanical properties (less than 50% of the initial tensile strength).

In FIG. 4e), the glass reinforced flexible polypropylene layer dominates in the tensile strength properties of the backsheet. Even when the polyamide layer loses its mechanical properties after heat aging, the full backsheet still keeps more than 50% of the initial tensile strength, provided of course the glass reinforced Flexible PolyPropylene is adequately heat stabilized.

The effect of glass fiber on the Emodulus of the layers is process dependent as the glass fibers are broken during compounding and extrusion. The data's are only indicative. Higher amount of glass fibers will compensate for loss of glass fiber length.

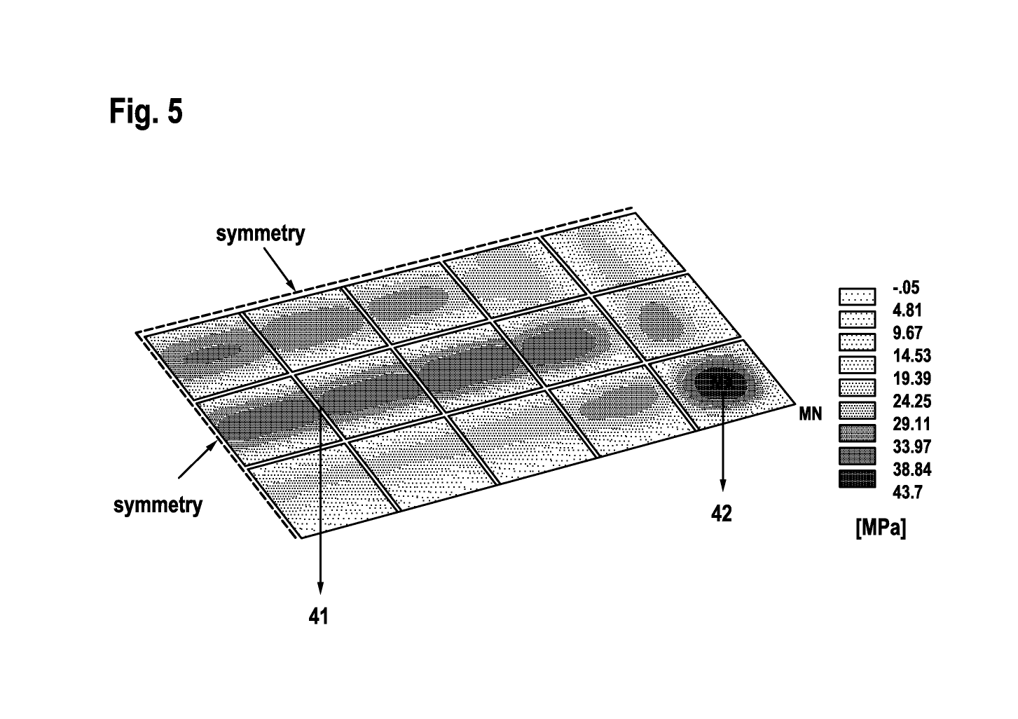

FIG. 5 show the stresses on the backside of PV cells of a 60 cells PV module (10*6 cells) under load of 2400 Pa, 1 second loading speed, 20° C.

The stresses are not uniform.

In some area, the stresses are higher along the interconnecting ribbons (41) and in other areas at the center of the PV cell (42).

Further, the maximum stress is not necessary relevant for a brittle material like a PV cell. Cracks will occur of course under stress but starting at defects: Lower stresses, but spread over a higher area, may cause cracks with a higher probability than very localized higher stresses.

It is therefore more relevant to calculate the probability of failure over the all area of all PV cells of the PV module. This exercise has been performed in function of several types of encapsulants and backsheets.

It has been discovered that softer backsheets may lead to localized higher stress but lead in reality to a lower probability of failure of the PV cells by cracking.

More rigid encapsulants than EVA, like VLDPE based encapsulants of a density of more than 0.88 g/cm³ (Tm >65° C.), transfer more stresses to the PV cells, but softer backsheet may compensate for this effect, especially if such backsheets have an high ability to relax (reduction of E-modulus in function of time), which is useful as snow load doesn't build up quickly.

Coextruded VLDPE/EVA films are softer than VLDPE films alone and more cost effective, while offering a protection against PID.

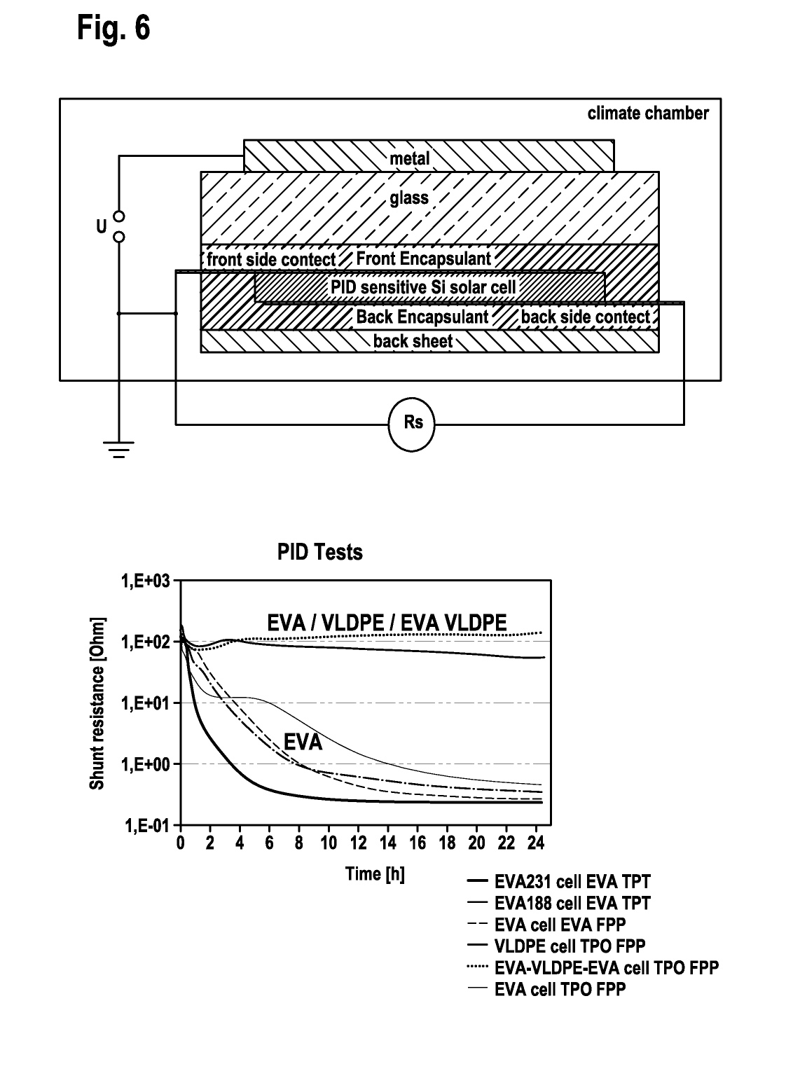

FIG. 6 shows a cross section of a PID test: The shunt resistance of an encapsulated PV cell (Glass/encapsulant/cell encapsulant/backsheet) is measured while the cell is grounded and the glass plate is brought to 300 Volts by metallic contact, creating an electric field from the glass plate towards the PV cell, through the front encapsulant.

The encapsulated cell is kept at 85° C./85% relative Humidity and the Shunt resistance is recorded in function of time.
When EVA is used as front encapsulant, the shunt resistance is reduced by a factor 10 in less than 24 hours.
When front encapsulants of the type EVA/VLDPE/EVA or VLDPE/EVA are used, the shunt resistance is marginally reduced after 24 hours in the same conditions.
When a purely VLDPE based front encapsulant (more expensive) is used, the shunt resistance is also marginally reduced, but slightly more, after 24 hours in the same conditions.

### EXAMPLES AND BEST MODE OF THE INVENTION

The invention will be further clarified by the following examples which are not meant to restrict the scope to the specific provided examples. Other combinations of the preferred features than those shown are also possible and useful.

### 1) Examples of Separation Layers and Backsheets Permeable to Acetic Acid:

One produces by coextrusion or coextrusion/lamination the following multi-layer films:
Film A):
“50 μm FPP (*) based layer/200 μm FPP (**) based layer with 12% glass fibers” (11)/25 μm RCPgMAH (***)based tie-layer (12d)/75 μm of PA 6, nucleated grade (12c)/25 μm of PEgMAH based tie-layer (12b)
Film B):
“50 μm FPP (*) based layer/25 μm RCPgMAH (***) based tie-layer/40 μm of PA 6, nucleated grade/25 μm RCPgMAH (***) based tie-layer/100 μm FPP (*) based layer, colaminated on 100 μm FPP (*) based layer” (11)/25 μm of RCPgMAH (***) based tie-layer (12d)/40 μm of PA 6, nucleated grade (12c)/25 μm of PEgMAH based tie-layer (12b)
Film C):
25 μm of PEgMAH based tie-layer (112b)/75 μm of PA 6 (7), nucleated grade/25 μm of PEgMAH based tie-layer (112b).
   (*) a blend of Hifax CA 10 A and Hifax CA 60, with usual additives (UV and heat stabilizers, like phenolic and phosphite anti-oxidants, possibly a thiosynergist, flame retardants like Magnesium Hydroxide, pigments like TiO2, . . . )
   (**) a blend 40 parts of Hifax CA 138 and 60 parts of Hifax CA 60, with usual additives (UV and heat stabilizers, flame retardants especially Magnesium Hydroxide with surface treatment, pigments like TiO2, . . . ) and treated (amino-silane) glass fibers (12% of the weight of the blend Hifax CA 138 and Hifax CA 60) with addition of PPgMAH compatibilizer adhesive resin (adhesive between the surface treated glass fibers and the FPP matrix).
   (***) a random copolymer of polypropylene preferably in blend with EPR rubber or another compatible rubber, functionalized (grafted) by reactive extrusion with maleic anhydride.

The permeability to acetic acid is estimated at 60° C. as follows: A stainless steal cup is filled with acetic acid and closed with the film under evaluation. The closed cup is weighed and put into a chamber evacuated by a vacuum pump at 60° C. during 14 days. The loss of weight of the closed cup is then measured and expressed in g/m².day.

The results are presented in comparison with a Tedlar/PET/Tedlar (TPT) film of 170 μm.

Film A: >100 g/m².day
Film B: >100 g/m².day
Film C: >300 g/m².day
TPT: <10 g/m².day (counter example)

Films A and B can be used as backsheet allowing high egress of acetic acid released from EVA encapsulant.

Film C can be used as internal insulating layer (7) avoiding trapping of acetic acid. It can be microperforated to further increase permeability. PA12, possibly in blend with polyolefins, can be used instead of PA6 to increase Oxygen permeability.

The TPT film can be useful as internal insulating layer (7) when micro-perforated. The amount of micro-perforation is adjusted to achieve a permeability to acetic acid of more than 20 g/m²·day.

Further Film A and B can be equipped with an integrated adhesive (13b/12a) to reduce production of acetic acid inside the PV module.

Further Film C can be embedded in or combined with polyethylene (VLDPE . . . ) based adhesive to reduce production of acetic acid inside the PV module.

### 2) Examples of Suitable FPP Blends and Films Thereof to Produce FPP Based Layers:

Following films are produced and evaluated for their Heat of fusion, cold foldability and acetic acid permeability (60° C.):

| | | Cold | Acetic Acid | |
|---|---|---|---|---|
| | Heat of | Foldability - | Perme- | |
| | fusion - | EN 495/5 | ability - | |
| Films | (J/g) | (° C.) | (g/m² · day) | E-modulus |
| 0.5 mm film on base | ±30 | <−40 | 200 | 120 |
| of Hifax CA 10 A or | | | | |
| CA 60 or CA 212 | | | | |
| 0.5 mm film on base | ±46 | <−40 | 85 | 400 |
| of Hifax CA 12 A | | | | |
| 0.5 mm film on base | ±52 | <−35 | 82 | 500 |
| of Hifax CA 138 | | | | |
| 0.5 mm film on base | ±19.5 | <−40 | 275 | |
| of Hifax CA 02 | | | | |
| 0.5 mm film on base | ±31 | <−40 | 220 | |
| of Hifax CA 7441 | | | | |
| Counter-example | ±104 | >−20 | 10 | >1500 |
| 0.5 mm film on base | | | | |
| of Homo PP Moplen | | | | |
| HP 456J | | | | |

The heat of fusion is measured at the second heating at 10 K/minute by integration of the heat of fusion from 80° C. to 180° C., with as heat flow baseline, the line between heat flow value at 0° C. and heat flow value at 180° C.

By comparing the heat of fusion of the FPP blend with a common PP resin, it is easy to select a suitable FPP blend. The heat of fusion of a suitable FPP blend will be less than 70% of the heat of fusion of a PP resin (reference PP resin is PP Moplen HP 456J), preferably less than 60%, more preferably less than 50%.

The cold bending test (EN 495/5) is a good way to recognize a suitable FPP based layer as low temperature cold foldability (−20° C., especially −40° C.) is difficult to achieve when the blend of PP and rubber is not (semi-)interpenetrated (if the PP and rubber phases are not co-continuous i.e. are separated).

The reference PP resin film, of Homo PP Moplen HP 456J, has a poor cold foldability and low permeability to acetic acid. Its high rigidity combined to a high CLTE may lead to unacceptable stresses to the PV cells. Its brittleness at low temperature constitutes a major safety hazard (cracks in backsheet and loss of electrical insulation). Addition of fillers to such PP will lead to extremely brittle material.

It has to be observed that the higher the heat of fusion, the lower the permeability to acetic acid. It is therefore preferred to select a FPP blend with a low heat of fusion, meaning a high rubber content.

Of course, when the FPP blend is completely melted at lamination temperature (typically 145 à 155° C.), the mechanical integrity of the backsheet may be compromised. If required, (especially when the e.g. PA6 based heat resistant layer of the backsheet has a low thickness, e.g. of less than 50 μm) the man skilled in the art will have a look to the DSC measurements (curves) of the FPP based layer(s) and select FPP blends which are not completely melted at lamination temperature (i.e. which have a residual heat of fusion above lamination temperature).

Addition of fillers (talcum, glass fibers) will further help to keep mechanical integrity during lamination, reduce CLTE and increase stiffness.

3) Examples of PA-FPP Backsheet with Good Heat Distorsion (Mechanical Integrity at Lamination Temperature) and Flow Resistance (Good Adhesion of EVA with PV Module Front Layer at Edges and Corners) and/or Elevated RTI or RTE (Heat Aging), Resistance to Humidity and Discoloration Even when Combined with EVA Encapsulants.

Addition of glass fibers in the FPP blend and combining the FPP blend based layers with a polyamide layer will much improve the retention of mechanical properties at lamination temperature and dimensional stability. Glass fibers help to control initial mechanical properties of all layers, in order to allow the FPP layers to dominate in the mechanical properties. Because FPP layers can be stabilized to achieve a RTI of typically 115° C., the backsheet achieves such result when the FPP layers dominate in the tensile strength of the backsheet. Further, the Polyamide innerlayer may protect the FPP layers and its anti-oxidants from degradation by peroxide attack when encapsulation films are used, provided with peroxides.

The FPP layers dominate in the mechanical properties because the FPP layers are reinforced (stiffened) and/or because the PA layer(s) have their mechanical properties reduced by inclusion of fillers especially glass fibers (reduced elongation) and/or inclusion of impact modifiers (reduced Emodulus). The thicknesses of all layers are adjusted to achieve dominance in the mechanical properties of the non PA layers.

### Example 3.1

One produces by coextrusion the following backsheet:
a) 60 μm of a PE-g-MAH based tie-layer (100 parts of LLDPE, possibly VLDPE grafted with maleïc anhydride; 10 parts of TiO2 Kronos 2220; 0.1 parts of low gas fading phenolic anti-oxidant ADK Stab AO-80; 0.3 parts of phosphite secondary anti-oxidant Weston 705; HALS: 0.3 parts of HALS Cyasorb UV 3529) (=12b).
b) 60 μm of a PA 6 based layer (100 parts of PA 6; 10 parts of TiO2 Kronos 2220; 0.3 parts of ADK Stab AO-80; 0.3 parts of Irgafos 168; HALS; PE-g-MAH carrier) (=12 c).
c) 30 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.15 parts of Irgafos 168) (=12d).
d) 200 μm of a glass fiber reinforced FPP compound (100 parts of Hifax CA 12A, peroxide cracked to adapt viscosity; 25 parts of treated glass fibers; 2 parts of PP-g-MAH compatibilizer; 35 parts of Mg(OH)2 surface treated, 10 parts of TiO2 Kronos 2220; 0.3 parts of Irganox 1010; 0.6 parts of Irganox PS 802; 0.15 parts of Irgafos 168, 0.5 parts of low reactivity HALS Cyasorb UV 3529—see (*)) (=11).
e) Optionally 50 μm of a FPP blend (Hifax CA 212, 100 parts; 10 parts of TiO2 Kronos 2220; 0.3 parts of Irganox 1010; 0.6 parts of Irganox PS 802 (**); 0.15 parts of Irgafos 168; 0.5 parts of low reactivity HALS Cyasorb UV 3529) (=11).
   (*) The length of the glass fibers (e.g. Lanxess CS 7952) is reduced to typically 500 μm during the compounding step (production of the glass reinforced compound on co-rotating twin screw extruders with kneading elements for adjusting glass fibers length), which limits the initial reinforcing effect of the glass fibers.
   (**) The thiosynergist (Irganox PS 802) may not be added in the external layer to avoid reducing the UV stability of the backsheet. Addition to the PP tie-layer (12d) is not preferred or performed with care, preferably on base of a master batch to reduce risk of interaction with the tie-layer (loss of adhesion)
   All parts are parts in weight.

The mean amount of filler (Sum of concentration in weight multiplied by thickness/Sum of thicknesses) in layers c) and d) is >30% weight of these layers; =(((10/110.45)*30+(70/173.55)*200)/230)=36%.

The mean heat of fusion of the resins of layers (12d-11), i.e. the sum for these layers of the heat of fusion of the resins multiplied with the thickness of the layer, divided by the thickness of all these layers, is less than 62.4 J/g; =((60*30)+(47*200))/230=48 J/g, where 60 J/g is the heat of fusion of the resin of the PP tie-layer (12d) and 47 J/g is the heat of fusion of the resin of the FPP layer (Blend Hifax CA 12/PPgMAH compatibilizer in ratio 100/2).

The Sum for all TPO layers (a), c), d)) of the Emodulus of the layer multiplied by its thickness is higher that the Sum for all heat resistant layers of the Emodulus of the layer multiplied by its thickness: (150*60+600*30+1000*200)=227.000>2.000*60=120.000.

The E-modulus of layer 12b is 150 MPa, of layer 12 c (PA6) is 2000 MPa, of layer 12d (PP tie-layer) is 600 MPa, of layer 11 (FPP with fillers) is 1000 MPa.

A sample of the backsheet is aged at 150° C. during 5 weeks. The tensile strength is measured according to Iso 527-3 and found superior to 50% of the initial value. It is further observed that no delamination occurs after 5 weeks heat aging. By extrapolation, on base of the activation energy for thermo-oxidation of PP, a RTI or RTE of +/−115° C. should be achieved.

It is further observed that addition of glass fibers in the FPP blend and combining the FPP blend based layers with a polyamide layer much improves the retention of mechanical properties at lamination temperature and dimensional stability/flow resistance (EVA adhesion at edges and corners of glass front layer) during module lamination (glass/EVA/cells/EVA/backsheet vacuum lamination—150° C. 15 minutes).

The produced backsheet (400 μm) provides a system voltage of more than 1200 VDC and more than 1000 VDC without optional layer e) (350 μm).

The system voltage of the backsheet is measured according to IEC 60664-1:2007.

The Flame Spread Index of the backsheet is measured (ASTM E162) and found lower than 100.

The backsheet of this invention, with only layers a) to d) (350 μm) is evaluated in comparison with a TPT backsheet (300 μm), with a FPP based backsheet (layer d of 350 μm without fillers), and a PP based backsheet (350 μm), with 20% EPR rubber, for:
E-modulus
CLTE (comparative measurement in TMA)
Acetic acid permeability, O2 permeability (OTR), water vapor permeability
Durability and effect on local corrosion:

Glass/EVA/crystalline silicon cells/EVA/backsheet (20 cells modules) are produced with or without inclusion of a separation layer inside the module (area of local corrosion). The modules are submitted to 2000 hours Heat Damp Test, 200 cycli of TCT and 10 cycli of humidity freeze (description: see IEC 61215) and are evaluated for electricity production (Loss of Pmax in %).

Stresses on interconnecting ribbons in Thermal Cycle Test (−40/+85° C.):
By finite element analysis, the number of thermal cycli leading to failure of interconnecting ribbons by fatigue is estimated (module construction=3.2 mm glass/EVA 460 μm/cells/EVA 460 μm/backsheet). Comparative results.
Because the encapsulant leads to mechanical coupling with the backsheet, a stiffer backsheet and/or a backsheet with an higher CLTE increases the amplitude of cell movements (opening and closure of the gap between cells) leading to quicker fatigue of the interconnecting ribbons between Cells.

Stresses on cells under load (2400 Pa):
By finite element analysis, the probability of failure of PV cells by cracking under snow load is assessed (snow load of 2400 Pa; time of loading=1 hour; 60 cells module with frame; construction=3.2 mm glass/EVA 460 μm/cells/EVA 460 μm/backsheet). Comparative results.

Because the encapsulants lead to mechanical coupling of the PV cells with glass and backsheet, a stiffer backsheet increases area of higher stress on PV cells and the probability of failure of such PV cells.

The results are in the following table.

| | | | | PP 20% |
|---|---|---|---|---|
| | | TPT | FPP | EPR |
| | | (refer- | (refer- | (limit |
| Test | Invention | ence) | ence) | invention) |
| E-modulus (MPa) | 1000 | 3500 | 400 | 1300 |
| CLTE (10⁻⁶/K) | 54 | 30 | 140 | 80 |
| Acetic Acid Permeability | >100 | <10 | >100 | 25 |
| (g/m² · day) | | | | |
| O2 permeability OTR | ±25 | ±10 | >250 | >250 |
| (cc/m² · day 1 atm 23° C. | | | | |
| 50% RH) | | | | |
| Water Vapor Permeability | ±2.5 | ±2.5 | ±2.5 | ±1 |
| (g./m² · day 40° C. 90% RH) | | | | |
| Loss of Pmax (%) without | ±5 | ±20 | ±5 | — (*) |
| separation layer | | | | |
| Loss of Pmax (%) with | ±5 | ±50 | ±20 | — (*) |
| TPT separation layer | | | | |
| Probability of failure (%) | 1.5 | 2 | 1.3 | 1.6 |
| Cycli to failure | 4800 | 4800 | 6000 | 3300 |

(*) Poor lamination is obtained with such backsheet (poor adhesion to EVA, stresses during cooling on the bussbars with probably as result an open circuit leading to poor initial Pmax.

It appears that the backsheet of the invention has:
An excellent figure of merit, i.e. a low “E-modulus*CLTE”
Excellent O2 barrier properties and Water vapor transmission rate (at the same level of TPT), while keeping a high permeability for acetic acid (egress of corrosive by-products).
Such barrier properties explain the low loss of power after aging:
   The oxygen barrier avoid local corrosion (no difference with and without TPT inner separation layer). It is not the case for the FPP based backsheet
   The high permeability to acetic acid delays cells corrosion. It is not the case for the TPT based backsheet.
Being softer, the backsheet of the invention leads to a reduced probability of failure of the PV cells, compared to TPT and PP based backsheets.
Thanks to the good figure of merit, the amplitude of movements in cell gaps is reduced significantly compared to PP based backsheet and at the level of TPT based backsheet.

The processing may lead to anisotropic properties with as result insufficient mechanical properties of the non PA layers in the cross machine direction. To compensate for such issues, several possibilities are available:
i. Reduce the thickness of the Polyamide layer (to e.g. 50 μm) and increase the thickness of the glass reinforced FPP layer (to e.g. 225 μm).
ii. Select a FPP blend with a higher amount of PP
iii. Add glass beads or platelet fillers to the formulation of the glass fiber reinforced FPP based layer (to reduce anisotropy)
iv. Add some fillers in the PA layer (to reduce elongation at break of such layer)

By increasing the thickness of layer d) from 200 μm to 400 μm (total thickness=600 μm) the backsheet provides a system voltage of more than 1500 VDC. The rubber content of layer d) can be increased to adjust softness and improve acetic acid permeability.

### Counter-Example 3.2

For comparison, layer b) is aged 2 weeks at 150° C. and found to have a tensile strength less than 50% of the initial value. The same is observed for the complete backsheet (a/b/c/d/e layers) when glass fibers are eliminated from composition of layer d).

### Example 3.3

A vacuum laminated (usual conditions for PV module i.e. 150° C.—15 minutes) sample of “Glass (3.2 mm)/EVA 0.46 mm (Vistasolar 486.10)*2/coextruded Backsheet of the example 3.1)” is aged 1000 hours at 85° C./85% relative humidity in the dark. The discoloration, i.e. yellowing (delta Yi—ASTM E313-73 (D1925)) is found acceptable (<10). After 7 days exposure of the dummy module outside, 30° slope, facing South, during the summer, in Belgium, the yellowing is reduced to less than 3 delta Yi.

The dummy module is further submitted to 200 thermal cycli (−40/+85)°. Neither delamination, nor cracking of the backsheet are observed.

### Example 3.4

Layer a) of example 3.1) is replaced by a 60 μm of a PE-g-MAH based tie-layer with formulation (without phenolic stabilizer): 100 parts of LLDPE grafted with maleïc anhydride; 10 parts of TiO2 Kronos 2220; 0.3 parts of Weston 705; HALS: 0.3 parts of Cyasorb UV 3529.

A vacuum laminated (usual conditions for PV module i.e. 150° C.—15 minutes) sample of “Glass (3.2 mm)/EVA 0.46 mm (Vistasolar 486.10)*2/coextruded Backsheet of the example 3.4)” is aged 1000 hours at 85° C./85% relative humidity. The discoloration (delta Yi—ASTM E313-73 (D1925)) is found acceptable (delta Yi<10). After 7 days exposure of the dummy module outside, 30° slope, facing South, during the summer, in Belgium, the yellowing is reduced to less than 3 delta Yi.

### Example 3.5

Same as example 3.4), but Nylostab S-EED (Clariant) is used in layer b) instead of ADK Stab AO-80.

A vacuum laminated (usual conditions for PV module i.e. 150° C.—15 minutes) sample of “Glass (3.2 mm)/EVA 0.46 mm (Vistasolar 486.10)*2/coextruded Backsheet of the example 3.5)” is aged 1000 hours at 85° C./85% relative humidity. The discoloration (delta Yi—ASTM E313-73 (D1925)) is found acceptable (delta Yi<10). After 7 days exposure of the dummy module outside, 30° slope, facing South, during the summer, in Belgium, the yellowing is reduced to less than 3 delta Yi.

### Counter-Example 3.6

For comparison, the phenolic anti-oxidant (ADK Stab AO-80) in layers a) and b) of example 3.1) is replaced by 0.3 phr of a standard anti-oxidant (Irganox 1010) sensitive to gas fading.

A vacuum laminated (usual conditions for PV module i.e. 150° C.—15 minutes) sample of “Glass (3.2 mm)/EVA 0.46 mm (Vistasolar 486.10)*2/coextruded Backsheet of the example 3.6)” is aged 1000 hours at 85° C./85% relative humidity. The discoloration (delta Yi—ASTM E313-73 (D1925)) is found unacceptable (delta Yi>10 and severe pinking is observed).

### Example 3.7

One produces by coextrusion the following backsheet:
a) 60 μm of a PE-g-MAH based tie-layer (100 parts of LLDPE grafted with maleïc anhydride; 10 parts of TiO2 Kronos 2220; 0.1 parts of ADK Stab AO-80; 0.3 parts of ADK STAB PEP-36; HALS: 0.3 parts of Cyasorb UV 3529).
b) 60 μm of a PA 6 based layer (100 parts of PA 6; 10 parts of TiO2 Kronos 2220; 0.3 parts of ADK Stab AO-80; 0.3 parts of ADK STAB PEP-36; HALS; PE-g-MAH carrier)
c) 30 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.6 parts of Irganox PS 802; 0.15 parts of Irgafos 168).
d) 125 μm of a glass fiber reinforced FPP compound (50 parts of Hifax CA 138; 50 parts of Hifax CA 60; 10 parts of treated glass fibers; 1 parts of PP-g-MAH compatibilizer; 10 parts of TiO2 Kronos 2220; 0.3 parts of Irganox 1010; 0.6 parts of Irganox PS 802; 0.15 parts of Irgafos 168—see (*))).
e) 25 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.6 parts of Irganox PS 802; 0.15 parts of Irgafos 168).
f) 50 μm of a Polyamide 12 layer (100 parts of PA 12; 10 parts of TiO2 Kronos 2220; 0.3 parts of ADK Stab AO-80; 0.3 parts of ADK STAB PEP-36; HALS) Such backsheet excels in heat resistance (2 layers of polyamide)

### Example 3.8

As example 3.1) but the glass fibers are included (10 parts) in the polyamide 6 based b) layer instead than in the FPP based d) layer.

A sample of the backsheet is aged at 150° C. during 5 weeks. The tensile strength is measured according to Iso 527-3 and found superior to 50% of the initial value. It is further observed that no delamination occurs after 5 weeks heat aging. By extrapolation, a RTI of +/−115° C. should be achieved.

The system voltage of the backsheet is >1000 VDC (IEC 60664-1:2007).

### Example 3.9

As example 3.1) but glass fibers are included (10 parts) in the polyamide 6 based b) layer and the amount of glass fiber in the FPP based d) layer is reduced to 10 parts instead of 20 parts.

A sample of the backsheet is aged at 150° C. during 5 weeks. The tensile strength is measured according to Iso 527-3 and found superior to 50% of the initial value. It is further observed that no delamination occurs after 5 weeks heat aging. By extrapolation, a RTI of +/−115° C. should be achieved.

It is further observed that addition of glass fibers in the FPP blend and combining the FPP blend based layers with a polyamide layer much improves the retention of mechanical properties at lamination temperature and dimensional stability during module lamination (glass/EVA/cells/EVA/backsheet vacuum lamination—150° C. 15 minutes).

### Example 3.10

One produces by coextrusion the following backsheet:
a) 60 μm of a PE-g-MAH based tie-layer (100 parts of LLDPE grafted with maleïc anhydride; 10 parts of TiO2 Kronos 2220; 0.1 parts of ADK Stab AO-80; 0.3 parts of ADK STAB PEP-36; HALS: 0.3 parts of Cyasorb UV 3529).
b) 60 μm of a PA 6 based layer (100 parts of PA 6; 10 parts of TiO2 Kronos 2220; 0.3 parts of ADK Stab AO-80; 0.3 parts of ADK STAB PEP-36; HALS; PE-g-MAH carrier)
c) 30 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.6 parts of Irganox PS 802; 0.15 parts of Irgafos 168).
d) 200 μm of a glass fiber reinforced FPP compound (50 parts of Hifax CA 138; 50 parts of Hifax CA 60; 10 parts of treated glass fibers; 1 part of PP-g-MAH compatibilizer; 10 parts of TiO2 Kronos 2220; 0.3 parts of Irganox 1010; 0.6 parts of Irganox PS 802; 0.15 parts of Irgafos 168—see (*))).
e) 50 μm of a FPP blend (Hifax CA 212, 100 parts; 10 parts of TiO2 Kronos 2220; 0.3 parts of Irganox 1010; 0.6 parts of Irganox PS 802; 0.15 parts of Irgafos 168).
   With the limited amount of glass fibers in the FPP layer, the coextrusion is easier. One produces a PV module (glass/EVA vistasolar 486.10 0.46 mm/cells/EVA vistasolar 486.10 0.46 mm/backsheet) with backsheet of example 3.10) by vacuum lamination—150° C. 15 minutes; 1 bar laminating pressure). The front EVA has good adhesion with the front layer (glass) even at PV module corners and edges.

### Counter-Example 3.11

Same as example 3.10) but no glass fibers are added in layer d). The front EVA has poor adhesion with the front layer (glass) at PV module corners and edges.

### Example 3.12

One produces by coextrusion the following backsheet:
a) 60 μm of a PE-g-MAH based tie-layer (100 parts of LLDPE grafted with maleïc anhydride; 10 parts of TiO2 Kronos 2220; 0.1 parts of ADK Stab AO-80; 0.3 parts of ADK STAB PEP-36; HALS: 0.3 parts of Cyasorb UV 3529).
b) 60 μm of a PA 6 based layer (100 parts of PA 6; 10 parts of TiO2 Kronos 2220; 0.3 parts of ADK Stab AO-80; 0.3 parts of ADK STAB PEP-36; HALS; PE-g-MAH carrier)
c) 30 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.6 parts of Irganox PS 802; 0.15 parts of Irgafos 168).
d) 200 μm of a FPP blend (Hifax CA 212, 100 parts; 10 parts of TiO2 Kronos 2220; 0.3 parts of Irganox 1010; 0.6 parts of Irganox PS 802; 0.15 parts of Irgafos 168).
   The system voltage of the Backsheet (IEC 60664-1:2007) is found to be more than 1000 VDC at a RTI rating of 90° C.

In adhesion layers c)-d) provide a system voltage of more than 600 VDC at a RTI rating of 110° C. or more and in adhesion layers c)-d) have a relative thermal endurance of 110° C. or more (IEC 60216-1 (2001-07)).

4) Example of a Front Encapsulant with EVA and VLDPE Layers, with Excellent Transparency, Compatibility of Additives and Allowing for Reduction of Potential Induced Degradation of PV Modules.

One produces by coextrusion a encapsulant comprising a core VLDPE based layer and two external layer on base of EVA (Emodulus=13 MPa):
100 μm EVA based layer
250 μm VLDPE based layer
100 μm EVA based layer

To achieve high transparency, the EVA has a VAc content of more than 25% and e.g. 33%.

To achieve high transparency, the VLDPE has a DSC melting peak (ISO 11357-3) temperature (Tm) of less than 100° C. but of more than 65° C. to limit risk of creep and is produced on base of single site catalyst technology (Engage or Exact types of VLDPE) with as example Exact® 82xx, where xx refers to the fluidity and 82 to the density (0.882 g/cm³). Such VLDPE has a Tm of 73° C. and a Emodulus of 35 MPa.

To be processed (coextrusion), the viscosity of the layers is adapted. In particular when peroxides are added for heat crosslinking, polymers with a MI of more than 10, preferably of more than 20, even more preferably of more than 25 (g/10 m; 190° C.; 2.16 kg) are preferred.

Each layers comprises usual additives, for example 0.1% of Tinuvin® 770 (common HALS), 0.2% of Irgafos 168 (phosphite anti-oxidant) and 0.3% of Chimassorb® 81 (UV absorber).

To achieve adhesion to glass and heat crosslinking during module lamination, silane and peroxide and possibly multi-functional crosslinkers are added to layers, for example 0.5% MEMO Silane (Gamma-Methacryloxypropyl trimethoxysilane) and 1.5% Luperox® TBEC and 0.5% of TAIC (Tria Allyl IsoCyanurate)

To achieve adhesion to glass and UV crosslinking after module lamination, silane and UV photoinitiators and possibly multi-functional crosslinkers are added to layers, for example 0.5% MEMO Silane (Gamma-Methacryloxypropyl trimethoxysilane) and 1% Benzophenone and 0.5% of TAIC (Tria Allyl IsoCyanurate)

After peroxide or UV crosslinking, it is observed than the adhesion between coextruded layers (EVA/VLDPE) is improved and become satisfactory.

It is also possible to achieve or improve crosslinking of the VLDPE based layer by humidity (on site) when the VLDPE is grafted with silane (by reactive extrusion), e.g. with 2% of VTMO. Condensation catalyst may be added to the VLDPE layer, possibly by migration from another (supplementary) layer (not equipped with grafted silane to avoid premature crosslinking) or from the backsheet.

After storage, it is observed that the additives are kept inside the encapsulant (compatibility with EVA). This is less the case when only VLDPE based layers are used.

PV modules (Glass/front encapsulant/PID sensitive cells/EVA/TPT backsheet) are produced with as front encapsulant EVA or the coextruded front encapsulant (EVA 33% VAc—VLDPE “8230”—EVA 33% VAc) of the example and submitted to heat and damps (85° C./85% Relative Humidity) under cell bias (Glass at 300 VDC and cells grounded). It is observed that the shunt resistance of the cells decreases quickly when a EVA front encapsulant is used, while it is more stable when the coextruded front encapsulant (EVA-VLDPE-EVA) is used.

The TPT backsheet is replaced with the backsheet of example 3.1) and the probability of failure of cells for a distributed load of 2400 Pa is reduced.

5) Example of FPP/PA Based Backsheet with a Stiffer PO (VLDPE Based) Rear Encapsulant than EVA, Protecting the Polyamide:

The backsheet of example 3.1) is further cextruded at the cell side with 340 μm of VLDPE (a blend of Exact 8210 (Tm=73° C.) and Exact 0210 (Tm=97° C.)) based layer (12a) and a 60 μm of a VLDPE based tie-layer (e.g. a blend of Exact 8210 and Exact 0210 functionalized by grafting Maleic AnHydride functionality) (13b), where such tie-layer provide adhesion to the rear side of the PV cells.

Such layers are preferably opaque to protect the polyamide from light (especially if PA MXD6 is used instead of PA 6). Viscosity adjustment of the VLDPE layer is provided to avoid that the encapsulant will flow above the PV cells;

Such VLDPE layers have an higher Emodulus than EVA, typically of between 35 and 90 MPa, while EVA has a Emodulus of typically 13 MPa (comparative measurements).

For standard PV modules (Glass/encapsulant/cells/encapsulant/TPT backsheet), this would mean that a higher stress is transmitted to the PV cells (higher probability of failure of PV cells) when the PV module is put under load (snow). Such effect is at least partly compensated when the TPT backsheet is replaced with the backsheet of this invention (e.g. from example 3.1) as such backsheet has a lower Emodulus and relax (reduction of Emodulus with time of loading) further better than TPT backsheet.

It has to be realized that the VLDPE layers (12a and 13b) can be partly cross-linked by the migrated peroxides of the front encapsulant (2), when such encapsulant (2) is provided with peroxides (EVA and/or VLDPE based), allowing the use for layers or rear encapsulant (12a, 13b) of resins of a DSC peak melting temperature of close to 73° C.

6) Example of a Corrosion and PID Resistant PV Module with VLDPE Based Encapsulant with Peroxide Crosslinking and a Cost Effective TPO Based Backsheet Comprising a Polyamide Based Layer Providing Protection Against Peroxide Degradation of the (F)PP Based Layers.

A PV module comprising following layers is produced:
i. 3.2 mm glass front sheet
ii. 0.46 mm Exact 8230 based encapsulant comprising 0.1% Tinuvin® 770, 0.2% Weston® 705, 0.3% Chimassorb® 81 and with 1.5% Luperox® TBEC and with preferably already grafted silanes (2% VTMO or MEMO).
iii. Interconnected PV cells
iv. like ii.
v. Backsheet of example 3.
   The PV module is aged at 150° C. during 12 days. No cracks are observed in the backsheet.

When only layer d) and e) of the backsheet of example 3) are used as backsheet (replacing v. in the PV module of example 5), severe “cracking” is observed after aging at 150° C. 12 days.

The same phenomena is observed when using standard EVA (peroxide crosslinkable encapsulants) in iv or in ii and iv.

### 7) Inclusion of a Fire Barrier:

One produces by coextrusion the following backsheet:
a) 60 μm of a PE-g-MAH based tie-layer (100 parts of LLDPE grafted with maleïc anhydride; 10 parts of TiO2 Kronos 2220; 0.1 parts of low gas fading phenolic anti-oxidant ADK Stab AO-80; 0.3 parts of phosphite secondary anti-oxidant Weston 705; HALS: 0.3 parts of Cyasorb UV 3529).
b) 60 μm of a PA 6 based layer (100 parts of PA 6; 10 parts of TiO2 Kronos 2220; 0.3 parts of ADK Stab AO-80; 0.3 parts of Irgafos 168; HALS; PE-g-MAH carrier)
c) 30 μm of a PP/EPR-g-MAH based tie-layer (100 parts of “PP-EPR” blend, grafted with maleïc anhydride; 10 parts of TiO2 Kronos 2220; 0.3 parts of Irganox 1010; 0.15 parts of Irgafos 168).
d) 200 μm of a glass fiber reinforced FPP compound (100 parts of Hifax CA 12A, peroxide cracked to adapt viscosity; 25 parts of treated glass fibers; 2 parts of PP-g-MAH compatibilizer; 35 parts of Mg(OH)2 surface treated, 10 parts of TiO2 Kronos 2220; 0.3 parts of Irganox 1010; 0.6 parts of Irganox PS 802; 0.15 parts of Irgafos 168, 0.5 parts of low reactivity HALS Cyasorb UV 3529—see (*)).
e) 50 μm of a TPO primer layer for adhesion with a fire barrier where the TPO primer layer maybe multi-layer and has a layer facing the fire barrier layer on base of a MAH or Acrylic acid functionalized co-PO blend (with 10 parts of TiO2 Kronos 2220; 0.3 parts of Irganox 1010; 0.15 parts of Irgafos 168; 0.5 parts of low reactivity HALS Cyasorb UV 3529) of a DSC melting peak (ISO 11357-3) temperature lower than lamination temperature.

One produces with the backsheet and a fire barrier a fire safe PV module (vacuum lamination at 150° C.) which comprises following layers:
Tempered Glass (3.2 mm)
EVA (460 μm)
Interconnected PV cells (Cr—Si)
EVA (460 μm)
The backsheet with as primer layer e) a layer based on ADMER SF 730-E
A fire barrier consisting of a closed amino-silane treated glass or basalt long fibers fabric of 200 g/m², coated at the non PV module side with a binder/protective resin like PDMS (silicone) or PUR (PolyUrethane) based;

The primer layer of the backsheet (MAH of Acrylic Acid modified) comes into contact with the amino-silane treated fibers and provides excellent adhesion (chemical reaction).

The primer layer may be partly crosslinked (e.g. by silane crosslinking and in this case, the co-PO of the primer layers(s) are grafted with silane crosslinkers) for improved reaction to fire.

The primer layer may be multi-layer, e.g. FPPgMAH based (side backsheet)/PEcoGMA based/(co-)PEgMAH based, for improved adhesion.

Examples 8 of Front Encapsulant with EVA and VLDPE Layers, with Excellent Transparency, Compatibility of Additives and Allowing for Reduction of Potential Induced Degradation of PV Modules.

One produces by coextrusion a encapsulant comprising a core VLDPE based layer and two external layer on base of EVA:
130 μm EVA based layer
200 μm VLDPE based layer
130 μm EVA based layer

To achieve high transparency, the EVA has a VAc content of more than 25% and of typically 33%. In such a case, the EVA layers have a Emodulus of 15 MPa or slightly less.

To achieve high transparency, the VLDPE has a DSC melting temperature of less than 100° C. and is produced on base of single catalyst technology (Engage or Exact types of VLDPE) with as example Exact® 82xx, where xx refers to the fluidity and 82 to the density (0.882 g/cm³). A layer on base of a VLDPE of 0.882 density has a Emodulus of typically 35 MPa.

The present multi-layer front encapsulant can therefore be quite soft, transparent and cost effective.

To be processed (coextrusion), the viscosity of the layers is adapted. In particular when peroxides are added for heat crosslinking, polymers with a Melt Index of more than 10, preferably of more than 20, even more preferably of more than 25 (g/10 m; 190° C.; 2.16 kg) are preferred. For EVA, a MI of 40 is typical.

Each layers comprises usual additives, for example 0.1% of Tinuvin® 770 (common HALS), 0.2% of Irgafos 168 (phosphite anti-oxidant) and 0.3% of Chimassorb® 81 (UV absorber).

To achieve adhesion to glass and heat crosslinking during module lamination, silane and peroxide and possibly multi-functional crosslinkers are added to layers, for example 1% MEMO Silane (Gamma-Methacryloxypropyl trimethoxysilane) and 1.5% Luperox® TBEC and 0.5% of TAIC (Tria Allyl IsoCyanurate).

To achieve adhesion to glass and UV crosslinking after module lamination, silane and UV photoinitiators and possibly multi-functional crosslinkers are added to layers, for example 1% MEMO Silane (Gamma-Methacryloxypropyl trimethoxysilane) and 1% Benzophenone and 0.5% of TAIC (Tria Allyl IsoCyanurate).

After peroxide or UV crosslinking, it is observed than the adhesion between coextruded layers (EVA/VLDPE) is improved and become satisfactory.

It is also possible to achieve or improve crosslinking of the VLDPE based layer by humidity (on site) when the VLDPE is grafted with silane (by reactive extrusion), e.g. with 2% of VTMO. Condensation catalyst may be added to the VLDPE layer, possibly by migration from another (supplementary) layer (not equipped with grafted silane to avoid premature crosslinking), possibly from a layer of the backsheet.

PV modules (Glass/front encapsulant/PID sensitive cells/EVA/TPT backsheet) are produced with as front encapsulant EVA (33% VAc) or the coextruded front encapsulant (EVA-VLDPE-EVA) as described above and submitted to heat and damps (85° C./85% Relative Humidity) under cell bias (Glass at 300 VDC and cells grounded). It is observed that the shunt resistance of the cells decreases quickly when a EVA front encapsulant is used, while it is more stable when the coextruded front encapsulant (EVA-VLDPE-EVA) is used.

As will be apparent the foregoing description does not cover all possible combinations. Other combinations may be derived by the man skilled in the art from the present description and are useful.

### LIST OF REFERENCE NUMBERS

1 front layer like glass plate
2 upper adhesive layer
4 photovoltaic cells, active material
5 rear encapsulant like EVA or tie-layer (13b)/soft co-PE (12a)
6 interconnected conductive ribbon,
66 interconnected conductive ribbon highly corroded
7 electrically insulating layer (embedded in 2 layers of EVA or in 2 sets of 113b/112a/112b layers)
10 Backsheet preferably including connecting layers (12) and possibly rear encapsulant (13b)/(12a) or Backsheet preferably including connecting layers (12) and a separated rear e.g. EVA encapsulant
11 FPP-PP based layers/backsheet
12a Encapsulating layer(s), preferably partly opaque to protect the heat resistant layer(s) (12c) from UV radiation.
12b TPO based tie-layer, preferably PE based, in adhesion with a heat resistant layer (12c) and providing adhesion to (part of) encapsulating layers (12a) or encapsulant film (5)
12c Heat resistant layer(s), at least one layer provided as barrier layer between encapsulant film or layers (5 or 12a/13b)
12d PP based tie-layer
13b PE based tie-layer in direct contact with the PV cells (4)
20 Membrane of the vacuum laminator
30 Lateral flow under pressure and heat (and later in the other direction during cooling)
40 Adhesion defect between glass (or front sheet) (1) and front encapsulant (2) (EVA or other front encapsulant like VLDPE based front encapsulant especially when having low viscosity and melting temperature) at the edges and especially corners of the PV modules

1. A multi-layer backsheet on base of:
a. A TPO primer layer or layers at the encapsulant side
b. Optionally a primer layer at the side opposite to the encapsulant side
c. Heat resistant layer or layers
d. PolyPropylene layer or layers comprising fillers, heat stabilizer and Flexible PolyPropylene
wherein
the total thickness of the TPO layers, the primer layer and the PolyPropylene layer or layers, is higher than the total thickness of the Heat resistant layer or layers, preferably 1.5 times higher, more preferably twice higher, even more preferably 3 times higher, even still more preferably 4 times higher and best 5 times higher,
at least one PolyPropylene layer is a tie-layer, and comprises a functionalized resin,
the mean heat of fusion of the resins of the PP based layers is less than 104*0.8 i.e. 83 J/g, preferably less than 104*0.7 i.e. 73 J/g, more preferably less than 104*0.6 i.e. 62.4 J/g, where the measurement of heat of fusion is performed as described in examples 2), i.e. in comparison with a PP homopolymer, Moplen HP 456J which has a heat of fusion of 104 J/g,
the mean amount of fillers in layer PP based layers, preferably in the TPO layers is more than 10% weight of these layers, preferably more than 15% weight, more preferably more than 20% weight, even more preferably more than 25% weight and most preferably more than 30% weight,
the mean amount of fibers fillers, preferably glass fibers, more preferably surface treated glass fibers, in the TPO layers is more than 3% weight of the said layers, preferably more than 5% weight, more preferably more than 10% weight,
the heat and UV stabilizer of the PolyPropylene layer or layers comprise phenolic, phosph(on)ite and synergist, preferably thio-synergist anti-oxidants and a HALS, in a mean concentration of at least 0.1% of the resin weight, preferably at least 0.3%, more preferably at least 1%, where the phenolic, phosph(on)ite and synergist is at least added in the composition of one of the PP based layer,
the heat resistant layer or layer(s) is/are based on polyolefin incompatible resin(s), having a DSC peak melting temperature (ISO 11357-3:2011) of at least 150° C., preferably of at least 170° C. and is/are preferably selected from Polyamide, EVOH, Polyester resins or blends thereof,
the backsheet comprises coextruded layers, preferably at least 3 layers, and at least one heat resistant layer or layer(s) react during coextrusion with the at least one PP tie-layer and the TPO primer layer,
the backsheet has an OTR of less than 100 cc/m².day 1 atm (23° C. 50% Relative Humidity), preferably less than 50 cc/m².day 1 atm (23° C. 50% Relative Humidity), more preferably less than 25 cc/m².day 1 atm (23° C. 50% Relative Humidity) and/or a CO2TR of less than 100 cc/m².day 1 atm (23° C. 50% Relative Humidity), preferably less than 50 cc/m².day 1 atm (23° C. 50% Relative Humidity), more preferably less than 25 cc/m².day 1 atm (23° C. 50% Relative Humidity).

2. The backsheet of claim 1, where the Sum for all TPO layers of the Emodulus of the layer multiplied by its thickness is higher than the Sum for all heat resistant layers of the Emodulus of the layer multiplied by its thickness.

3. The backsheet of claim 1, wherein heat resistant layer or layers are based on Polyamide, preferably on Polyamide 6, or on Polyamide MXD6, or on Polyamide 6I/6T or blends thereof, preferably heat stabilized polyamide and the polyamide based layer(s) are preferably protected from light, by coextruded layers comprising pigments, on the side of the encapsulant by TPO primer layer or layers and preferably encapsulating layer and possibly tie-layer AND on the opposite side by PP based layers, such layers comprising pigments in a mean area concentration of at least 1 g/m² of protecting layers, preferably 5 g/m², more preferably 10 g/m², of preferably white pigments, preferably TiO2, preferably rutile type, preferably coated with an inorganic layer to prevent photocatalytic activity and an organic layer to improve dispersion.

4. The backsheet of claim 1, where the thickness of the polyamide based layer(s) is not more than 40%, preferably not more than 25%, most preferably not more than 20% of the total backsheet thickness and the polyamide based layers are encapsulated within pigmented polyolefin based layers.

5. The backsheet of claim 1, coextruded at the cell side with PE based layer or layers having an Emodulus of 1.5 times to 10 times the Emodulus of an EVA based encapsulant with 33% VinylAcetate, preferably 2 to 8 times, i.e. an Emodulus between typically 20 and 150 MPa, preferably between 30 and 100 MPa, while the Emodulus of the backsheet is less than 70%, preferably less than 50%, more preferably less than 30% of the Emodulus of a TPT backsheet, i.e. the backsheet, which will be further combined with said PE encapsulant, has an Emodulus lower than 2500 MPa, preferably lower than 1750 MPa, more preferably lower than 1050 MPa.

6. The backsheet of claim 5, where the PE based layer or layers comprise a VLDPE based layer having a DSC peak melting temperature (ISO 11357) of more than 65° C., preferably of more than 75° C. and of less than 110° C., preferably of less than 100° C., such layer not comprising a free radical initiator, like peroxides.

7. The backsheet of claim 1 comprising platelets fillers.

8. The backsheet of claim 3 where the polyamide is provided in blend with polyolefin to reduce the dielectric constant and hygroscopicity of the polyamide.

9. The backsheet of claim 1, in a thickness of at least 500 μm, allowing to achieve a system voltage rating of 1500 VDC (IEC 60664-1, IEC61730), while the Emodulus of the backsheet is less than 70%, preferably less than 50%, more preferably less than 30% of the Emodulus of a TPT backsheet, i.e. the backsheet has an Emodulus lower than 2500 MPa, preferably lower than 1750 MPa, more preferably lower than 1050 MPa.

10. A PV module comprising a peroxide cross-linked encapsulant and the backsheet of claim 3, where the polyamide layer facing the PV cells is heat stabilized by a non phenolic heat stabilizers, especially of the type of Nylostab SEED® or by a specific phenolic anti-oxidant being of the type of Adeka AO 80® or of the type of Irganox 245® and doesn't include a Cu/I based anti-oxidant system at least in layers coming in contact with PO tie-layers.

11. A PV module comprising free radicals crosslinked encapsulants, preferably VLDPE or VLDPE/EVA based, and a backsheet of claim 1 where a heat resistant layer acts as barrier layer avoiding degradation of the backsheet by migrated free radicals initiators and/or radicals.

12. A PV module comprising any backsheet described in claim 1 and a front encapsulant film comprising at least one non polar co-PE based layer and at least one polar co-PE based layer, preferably cross-linked, to achieve better in field interlayer adhesion.

13. A coextruded encapsulant film on base of EVA layer(s) and VLDPE layer(s), where the VLDPE layer(s) have a DSC melting peak temperature of more than 65° C., preferably of more than 70° C., more preferably of more than 75° C. and of less than 110° C., more preferably of less than 100° C., comprising free radicals initiators.

14. A PV module comprising an inner-insulation layer with high permeability to degradation by-products and to oxygen by at least the one of micro-perforation or composition, such composition preferably based on polyolefins and/or polyamide layers and/or blends thereof.

15. A PV module comprising an inorganic based fire barrier attached to a TPO based primer layer at the rear side of the backsheet, where the TPO primer layer has preferably a DSC peak melting temperature lower than module lamination temperature of typically 145° C. to 155° C., more preferably lower than 140° C., where the TPO is preferably functionalized and where the fire barrier is preferably on base of with silane treated inorganic fibers, preferably glass or basalt based fibers, e.g. provided as a fabric, preferably as a closed fabric, where the fabric is preferably coated at the side opposite to the PV cells with a protective coating e.g. on base of PDMS or PUR, and where the TPO based primer layer is advantageously multi-layer and/or partly cross-linked, preferably on base of silane cross-linkers.
